(19) United States
(12) Patent Application Publication
(10) Pub. No.: US 2023/0221642 A1
(43) Pub. Date: Jul. 13, 2023

(54) MASK, MASK ASSEMBLY HAVING THE SAME, AND SUBSTRATE TRANSFER APPARATUS

(71) Applicant: Samsung Display Co., Ltd., Yongin-si (KR)

(72) Inventors: CHEOLRAE JO, Yongin- si (KR); CHEOLLAE ROH, Seongnam-si (KR); SANGJIN HAN, Seoul (KR); SEUNGHO MYOUNG, Hwaseong-si (KR)

(73) Assignee: Samsung Display Co., Ltd., Yongin-si (KR)

(21) Appl. No.: 18/083,719

(22) Filed: Dec. 19, 2022

(30) Foreign Application Priority Data
Jan. 13, 2022 (KR) 10-2022-0005396

(51) Int. Cl. G03F 7/09; G03F 1/60; G03F 1/68

(52) U.S. Cl. CPC G03F 7/09; G03F 1/60; G03F 1/68; G01C 19/04

(57) ABSTRACT

A mask, a mask assembly including a mask, and a substrate transfer apparatus including a mask. According to an embodiment, a mask includes a frame including an opening, accommodation structure disposed on the frame and including an accommodation space shielded from an outside, and a sensor disposed in the accommodation space.

### CROSS-REFERENCE TO RELATED APPLICATION(S)

This U.S. non-provisional patent application claims priority to and benefits of Korean Patent Application No. 10-2022-0005396 under 35 U.S.C. § 119, filed on Jan. 13, 2022 in the Korean Intellectual Property Office, the entire contents of which are hereby incorporated by reference.

### BACKGROUND

### 1. Technical Field

The disclosure relates to a mask including a sensor, a mask assembly including the mask, and a substrate transfer apparatus including the mask.

### 2. Description of the Related Art

A display panel includes multiple pixels. Each pixel includes a driving element such as a transistor and a display element such as an organic light emitting element. The display element may be formed by stacking electrodes and various functional layers on a substrate.

The functional layers of the display element may be deposited using masks through which openings may be defined. An apparatus that may be used to deposit the functional layers includes a transfer path to transfer a substrate or a mask between process chambers and a deposition chamber in which a deposition process may be performed. The transfer path may be provided as a chamber in a vacuum state for the connection with the deposition chamber. Defects can occur in an object in transfer such as a substrate or a mask due to object flaw or a collision with the apparatus used in the deposition process. It may be difficult to determine whether the defects are caused by the object in transfer or the apparatus used in the deposition process, and thus, performing a repair process corresponding to the defects may be restricted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a mask and a mask assembly, which may be capable of real-time monitoring while moving a substrate transfer apparatus.

The disclosure provides a substrate transfer apparatus capable of real-time monitoring of the mask and the mask assembly.

According to an embodiment, a mask may include a frame including an opening, accommodation structure disposed on the frame and defining an accommodation space shielded from an outside, and a sensor disposed in the accommodation space.

The sensor may include at least one of a displacement sensor, a gyro sensor, and a vibration sensor.

The mask may further include a camera attached to the frame.

The mask may further include a communication transceiver electrically connected to the sensor.

The mask may further include a driving circuit disposed in the accommodation space and electrically connected to the sensor.

The mask may further include a driving circuit electrically connected to the sensor. The accommodation structure may include a first accommodation part defining a first part accommodation space and a second accommodation part defining a second part accommodation space. The sensor may be disposed in the first part accommodation space. The driving circuit may be disposed in the second part accommodation space.

The second accommodation part may at least partially overlap the opening in a plan view.

The frame may further include a portion overlapping the second accommodation part and crossing the opening, and the opening may be divided into two openings by the portion.

The mask may further include a mask sheet disposed on the frame and including mask openings defined through the mask to overlap the opening in a plan view.

The accommodation structure may be disposed on the mask sheet and may overlap at least a portion of the mask openings of the mask sheet.

The accommodation structure may include a cover physically connected to the frame, the frame and the cover may together define the accommodation space, and the accommodation space may have atmospheric pressure.

The accommodation structure may include an accommodation portion disposed on the frame, and a cover covering the accommodation portion, the accommodation portion and the frame may together define the accommodation space, and the accommodation space may have atmospheric pressure.

According to an embodiment, a mask assembly may include a mask including a frame including an opening, and a first sensor, and accommodation structure defining an accommodation space, a carrier substrate disposed on the mask and including a side facing the mask, and another side opposite to the side facing the mask, and a substrate disposed between the mask and the carrier substrate and provided to the side facing the mask. The first sensor may be accommodated in the accommodation space.

The sensor may include at least one of a gyro sensor, a vibration sensor, and a displacement sensor.

The carrier substrate may further include a camera, and a second sensor.

The carrier substrate may further include another accommodation structure defining another accommodation space, the second sensor may be accommodated in the another accommodation space, and at least one of the accommodation space and the another accommodation space may have atmospheric pressure.

The another accommodation space may include a first accommodation part and a second accommodation part, that are of the another side of the carrier substrate.

According to an embodiment, a substrate transfer apparatus may include a path providing a vacuum state, a transfer guide disposed in the path and including bottom rollers and side rollers, and a mask moving along the transfer guide. The mask may include a frame including an opening, accommodation structure disposed on the frame and including accommodation space, and a sensor disposed in the accommodation space.

The sensor may include at least one of a gyro sensor, a vibration sensor, and a displacement sensor, and at least one of the bottom rollers and the side rollers may be in physical contact with the accommodation structure.

The substrate transfer apparatus may further include an inner communication transceiver disposed on the mask, and an external communication transceiver disposed outside the path to transmit and receive a signal to and from the inner communication transceiver.

According to the above, it may be possible to monitor a movement environment of the mask or the mask assembly in real time. Accordingly, damages may be prevented from occurring in a transferring process of the mask or the mask assembly, and a process cost may be reduced.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic diagram of a substrate transfer apparatus according to an embodiment of the disclosure;

FIG. 2 is a schematic cross-sectional view of a deposition chamber according to an embodiment of the disclosure;

FIGS. 3A and 3B are schematic cross-sectional views of a portion of a deposition chamber according to an embodiment of the disclosure;

FIGS. 3C and 3D are schematic cross-sectional views of a display panel according to an embodiment of the disclosure;

FIG. 4 is an exploded schematic perspective view of a mask according to an embodiment of the disclosure;

FIGS. 5A and 5B are assembled schematic perspective views of a mask according to an embodiment of the disclosure;

FIGS. 6A and 6B are schematic cross-sectional views of a portion of a mask according to embodiments of the disclosure;

FIG. 7 is a schematic plan view of a mask according to an embodiment of the disclosure;

FIGS. 8A to 8C are schematic views of a portion of a path according to an embodiment of the disclosure;

FIGS. 9A and 9B are schematic plan views of a mask according to an embodiment of the disclosure;

FIG. 10A is an exploded schematic perspective view of a mask according to an embodiment of the disclosure;

FIG. 10B is an assembled schematic plan view of the mask shown in FIG. 10A;

FIG. 10C is an assembled schematic perspective view of the mask shown in FIG. 10A;

FIGS. 11A and 11B are schematic perspective views of a substrate transfer member;

FIG. 11C is a schematic rear view of the substrate transfer member; and

FIG. 12 is an exploded schematic perspective view of a mask assembly according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the disclosure, it will be understood that when an element (or area, layer, or portion) is referred to as being “on”, “connected to” or “coupled to” another element or layer, it can be directly on, connected or coupled to the other element or layer or intervening elements or layers may be present. It will be understood that the terms “connected to” or “coupled to” may include a physical or electrical connection or coupling.

Like numerals refer to like elements throughout. In the drawings, the thickness, ratio, and dimension of components may be exaggerated for effective description of the technical content.

As used herein, the term “and/or” may include any and all combinations of one or more of the associated listed items. For example, “A and/or B” may be understood to mean any combination including “A, B, or A and B.” The terms “and” and “or” may be used in the conjunctive or disjunctive sense and may be understood to be equivalent to “and/or.”

It will be understood that, although the terms “first,” “second,” etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprise,” “comprising,” “has,” “having,” “include,” and/or “including” specify the presence of stated features, integers, steps, operations, elements, and/or components, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

“About,” “approximately,” and “substantially” are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

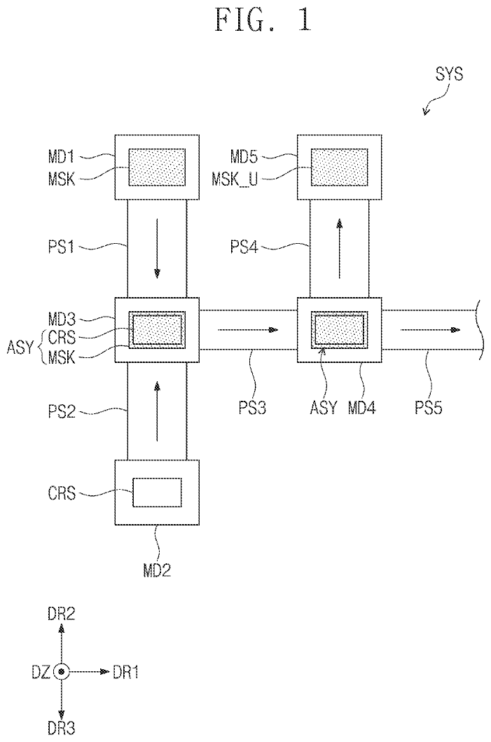

FIG. 1 is a schematic diagram of a substrate transfer apparatus SYS according to an embodiment of the disclosure. The substrate transfer apparatus SYS may include various transfer guides and chambers. As an example, the substrate transfer apparatus SYS may include multiple chambers MD1, MD2, MD3, MD4, and MD5 and paths PS1, PS2, PS3, PS4, and PS5 connected to the chambers MD1, MD2, MD3, MD4, and MD5. FIG. 1 shows some components of the substrate transfer apparatus SYS.

Each of the chambers MD1, MD2, MD3, MD4, and MD5 may provide a separate space. The chambers MD1, MD2, MD3, MD4, and MD5 may be provided independently from each other. FIG. 1 shows first, second, third, fourth, and fifth chambers MD1, MD2, MD3, MD4, and MD5.

The first chamber MD1 may provide the space in which a mask MSK may be stored and loaded. The first chamber MD1 may accommodate at least one mask MSK. The first chamber MD1 may be controlled to be maintained in a vacuum state or to be switched from the vacuum state to an atmosphere state or vice versa. In an embodiment, the first chamber MD1 may be provided as a single space, however, according to an embodiment, the first chamber MD1 may include multiple chambers including one or more paths. Although not shown in figures, the first chamber MD1 may be connected to another chamber in which the mask MSK may be stored via a path and may serve as a space where the mask MSK moved from the storage chamber waits to be loaded.

The second chamber MD2 may provide the space in which a substrate transfer member CRS may be stored or loaded. The substrate transfer member CRS may include a substrate described later and a carrier substrate. Although not shown in figures, the second chamber MD2 may be connected to a separate path to receive the substrate transfer member CRS. The second chamber MD2 may be controlled to be maintained in a vacuum state or to be switched from the vacuum state to an atmosphere state or vice versa.

The third chamber MD3 may provide the space in which a mask assembly ASY may be generated or accommodated. The mask assembly ASY may include the substrate transfer member CRS and the mask MSK. The mask MSK and the substrate transfer member CRS may be coupled to each other in the third chamber MD3 to form the mask assembly ASY. The third chamber MD3 may be controlled to be maintained in a vacuum state or to be switched from the vacuum state to an atmosphere state or vice versa.

The fourth chamber MD4 may be a deposition chamber. In the fourth chamber MD4, an organic material may be deposited on the mask assembly ASY. The fourth chamber MD4 may be maintained in a vacuum state during the deposition process, and after the deposition process, the fourth chamber MD4 may be maintained in the vacuum state or may be switched to an atmosphere state.

The fifth chamber MD5 may provide the space in which a used mask MSK_U may be unloaded or stored. The used mask MSK_U may be a mask that may be separated from the mask assembly ASY after the deposition process. An operation of separating the used mask MSK_U from the mask assembly ASY may be performed in the fourth chamber MD4, however, embodiments are not limited thereto or thereby. The separation operation of the used mask MSK_U may be performed in another chamber rather than the fourth chamber MD4, and the fifth chamber MD5 may be connected to the chamber in which the separation operation of the used mask MSK_U may be performed via a path. The fifth chamber MD5 may be controlled to be maintained in a vacuum state or to be switched from the vacuum state to an atmosphere state or vice versa.

The paths PS1, PS2, PS3, PS4, and PS5 may be disposed between the chambers MD1, MD2, MD3, MD4, and MD5 and may connect the chambers MD1, MD2, MD3, MD4, and MD5 to each other. Each of the paths PS1, PS2, PS3, PS4, and PS5 may include a transfer guide. Each of the paths PS1, PS2, PS3, PS4, and PS5 may be driven independently from each other and may be maintained in the vacuum state or the atmosphere state. FIG. 1 shows first, second, third, fourth, and fifth paths PS1, PS2, PS3, PS4, and PS5 as a representative example.

The first path PS1 may be disposed between the first chamber MD1 and the third chamber MD3. The mask MSK provided from the first chamber MD1 may be provided to the third chamber MD3 via the first path PS1. The first path PS1 may move the mask MSK in a direction from the first chamber MD1 to the third chamber MD3, i.e., a third direction DR3.

The second path PS2 may be disposed between the second chamber MD2 and the third chamber MD3. The substrate transfer member CRS provided from the second chamber MD2 may be provided to the third chamber MD3 via the second path PS2. The second path PS2 may move the substrate transfer member CRS in a direction from the second chamber MD2 to the third chamber MD3, i.e., a second direction DR2.

The third path PS3 may be disposed between the third chamber MD3 and the fourth chamber MD4. The mask assembly ASY provided from the third chamber MD3 may be provided to the fourth chamber MD4 via the third path PS3. The third path PS3 may move the mask assembly ASY in a direction from the third chamber MD3 to the fourth chamber MD4, i.e., a first direction DR1.

The fourth path PS4 may be disposed between the fourth chamber MD4 and the fifth chamber MD5. The used mask MSK_U to be accommodated in the fifth chamber MD5 may be provided to the fifth chamber MD5 via the fourth path PS4. The fourth path PS4 may move the used mask MSK_U in the second direction DR2.

The fifth path PS5 may be connected to the fourth chamber MD4. Although not shown in figures, the fifth path PS5 may connect the fourth chamber MD4 to another module. The fifth path PS5 may move the substrate transfer member CRS, which may be obtained by removing the used mask MSK_U from the mask assembly ASY and provided from the fourth chamber MD4, in the first direction DR1. The substrate transfer member CRS may move to another module via the fifth path PS5.

In an embodiment, the paths PS1, PS2, PS3, PS4, and PS5 are separated from each other and connect the chambers to each other, however, this is merely an example. According to an embodiment, the paths PS1, PS2, PS3, PS4, and PS5 may be connected to each other to form a single path and may be connected to each other via individual chambers. The paths PS1, PS2, PS3, PS4, and PS5 may be provided in one transfer chamber, and each of the chambers may be connected to a lower portion of the transfer chamber. The mask MSK, the substrate transfer member CRS, or the mask assembly ASY may move along the single path corresponding to the transfer chamber, and the mask MSK, the substrate transfer member CRS, or the mask assembly ASY may be loaded onto each corresponding chamber in which a deposition, an assembly, or a separation process may be performed. The substrate transfer apparatus SYS may be designed in various ways as long as the substrate transfer apparatus SYS includes the path through which the mask MSK, the substrate transfer member CRS, or the mask assembly ASY may be transferred.

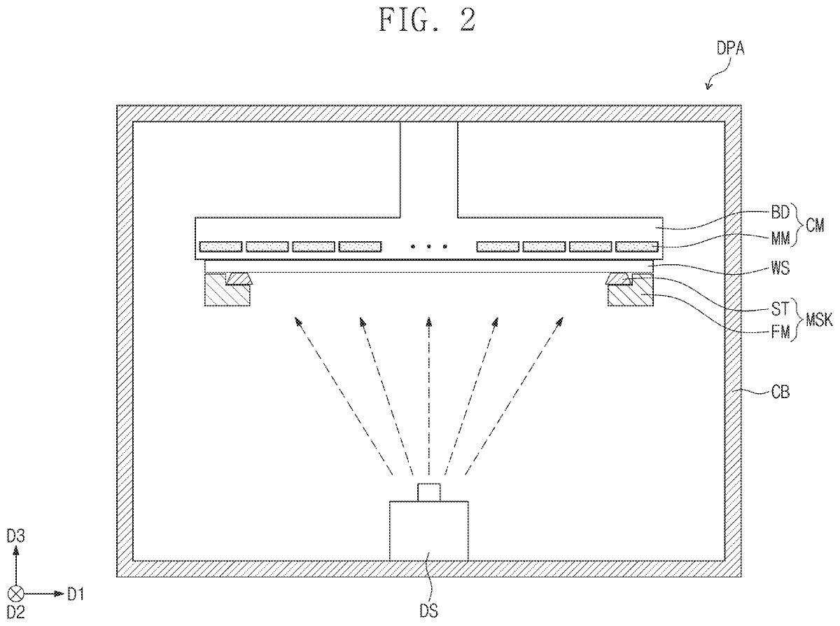

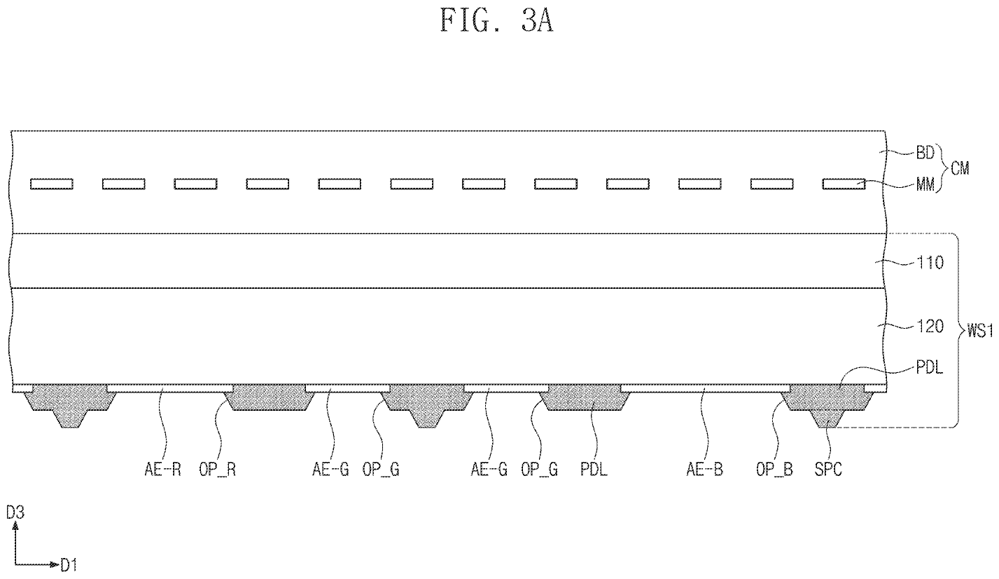

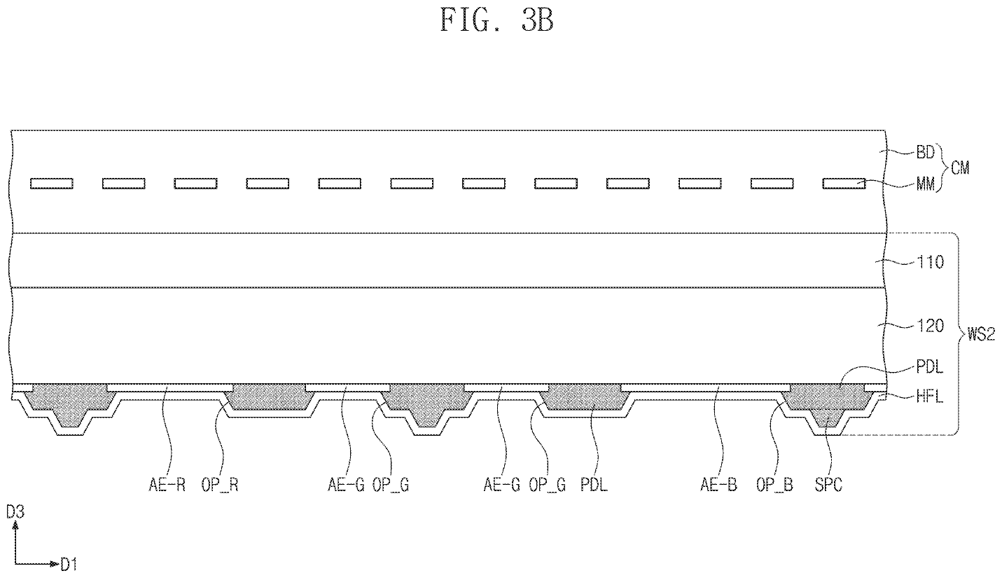

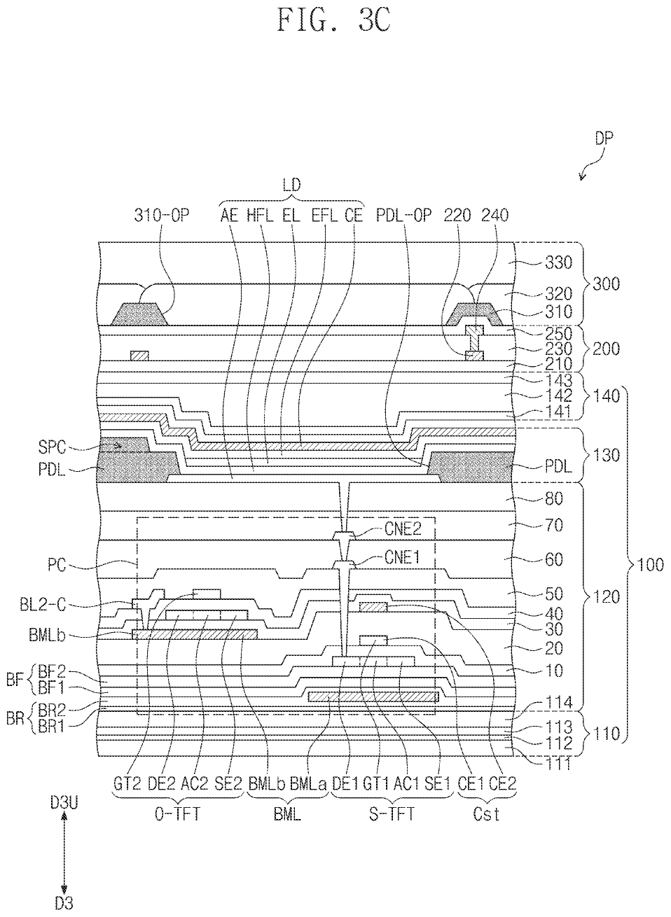

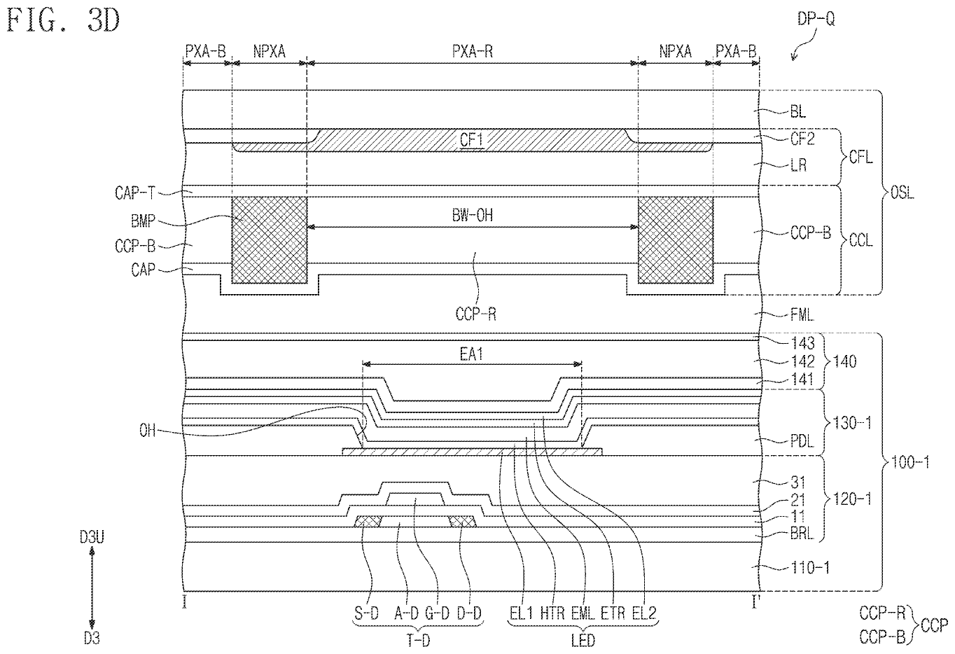

FIG. 2 is a schematic cross-sectional view of a deposition chamber DPA according to an embodiment of the disclosure. FIGS. 3A and 3B are schematic cross-sectional views of a portion of the deposition chamber according to an embodiment of the disclosure. FIGS. 3C and 3D are schematic cross-sectional views of display panels DP and DP-Q according to embodiments of the disclosure.

FIG. 3A shows the deposition chamber before the deposition process, and FIG. 3B shows the deposition chamber after the deposition process. FIG. 3C shows the display panel obtained after all processes may be completed. FIG. 3D shows the display panel according to an embodiment of the disclosure. Hereinafter, the disclosure will be described with reference to FIGS. 2 and 3A to 3D.

The deposition chamber DPA shown in FIG. 2 may correspond to the fourth chamber MD4. The deposition chamber DPA may be used for a process to form a layer using a chemical vapor deposition in a manufacturing process of the display panel DP.

A deposition condition of the deposition chamber DPA may be set to a vacuum state. The deposition chamber DPA may include a bottom surface, a ceiling surface, and sidewalls. The bottom surface of the deposition chamber DPA may be substantially parallel to a plane defined by a first directional axis D1 and a second directional axis D2. A third directional axis D3 may indicate a normal line direction of the bottom surface of the deposition chamber DPA. Hereinafter, the first to third directional axes D1 to D3 may be defined independently from the first to third directions DR1 to DR3 shown in FIG. 1. In the expression “when viewed in a plane or in a plane” or “in a plan view” used in FIGS. 2 and 3A to 3D, the plane may be set based on a plane substantially parallel to the first directional axis D1 and the second directional axis D2.

The deposition chamber DPA may be used to form the conductive layer or the insulating layer deposited over an entire surface of the display panel DP among components of the display panel DP. Referring to FIG. 3C, the display panel DP may include a display layer 100, a sensor layer 200, and an anti-reflective layer 300.

The display layer 100 may have a configuration that generates an image. The display layer 100 may be a light emitting type display layer. For example, the display layer 100 may be an organic light emitting display layer, an inorganic light emitting display layer, an organic-inorganic light emitting display layer, a quantum dot display layer, a micro-LED display layer, or a nano-LED display layer. The display layer 100 may include a substrate 110, a circuit layer 120, a light emitting element layer 130, and an encapsulation layer 140, which may be stacked on each other in an upward direction D3U. The upward direction D3U may be a direction opposite to third directional axis D3 in which a deposition material may be supplied to a work substrate WS provided to the deposition chamber DPA.

The substrate 110 may include layers 111, 112, 113, and 114. As an example, the substrate 110 may include a first sub-base layer 111, a first intermediate barrier layer 112, a second intermediate barrier layer 113, and a second sub-base layer 114. The first sub-base layer 111, the first intermediate barrier layer 112, the second intermediate barrier layer 113, and the second sub-base layer 114 may be sequentially stacked on each other in the upward direction D3U.

Each of the first sub-base layer 111 and the second sub-base layer 114 may include at least one of a polyimide-based resin, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the disclosure, the term “X-based resin” means that a functional group of “X” may be included in the resin. A barrier layer BR may be disposed on the substrate 110.

Each of the first and second intermediate barrier layers 112 and 113 may include an inorganic material. Each of the first and second intermediate barrier layers 112 and 113 may include at least one of silicon oxide, silicon nitride, silicon oxynitride, and amorphous silicon. As an example, each of the first sub-base layer 111 and the second sub-base layer 114 may include polyimide, the first intermediate barrier layer 112 may include silicon oxynitride (SiON), and the second intermediate barrier layer 113 may include silicon oxide (SiOX).

For example, the first intermediate barrier layer 112 may have a refractive index having a value between a refractive index of the first sub-base layer 111 and a refractive index of the second intermediate barrier layer 113. As a difference in refractive index between layers that may be in contact with each other decreases, a reflection of the light at an interface between the layers that may be in contact with each other may be reduced. However, this is merely an example, and each of the layers may include various materials and embodiments are not particularly limited.

The first sub-base layer 111 may have a thickness greater than a thickness of the second sub-base layer 114, however, embodiments are not limited thereto or thereby. A thickness of the first intermediate barrier layer 112 may be smaller than a thickness of the second intermediate barrier layer 113. However, the thickness of each of the first and second intermediate barrier layers 112 and 113 is not limited thereto or thereby.

The circuit layer 120 may include a pixel circuit PC and insulating layers BR, BF, and 10 to 80. The insulating layers BR, BF, and 10 to 80 may include the barrier layer BR, a buffer layer BF, and first, second, third, fourth, fifth, sixth, seventh, and eighth insulating layers 10, 20, 30, 40, 50, 60, 70, and 80, which may be arranged in the upward direction D3U.

The pixel circuit PC may include a light blocking layer BML, thin film transistors S-TFT and O-TFT, and a capacitor Cst. The pixel circuit PC may form a pixel PX with a light emitting element LD. The pixel PX may include the thin film transistors S-TFT and O-TFT and the light emitting element LD. For convenience of explanation, FIG. 3B shows two thin film transistors S-TFT and O-TFT (hereinafter, referred to as a first thin film transistor and a second thin film transistor, respectively) as a representative example. According to an embodiment, the number of the thin film transistors of the pixel PX may be changed in various ways and is not particularly limited.

The barrier layer BR may be disposed on the substrate 110. The barrier layer BR may include a first sub-barrier layer BR1 disposed on the substrate 110 and a second sub-barrier layer BR2 disposed on the first sub-barrier layer BR1.

Each of the first and second sub-barrier layers BR1 and BR2 may include an inorganic material. Each of the first and second sub-barrier layers BR1 and BR2 may include at least one of silicon oxide, silicon nitride, silicon oxynitride, and amorphous silicon. As an example, the first sub-barrier layer BR1 may include silicon oxynitride (SiON), and the second sub-barrier layer BR2 may include silicon oxide (SiOX).

The first sub-barrier layer BR1 may have a refractive index having a value between a refractive index of the second sub-base layer 114 and a refractive index of the second sub-barrier layer BR2. As a difference in refractive index between layers that may be in contact with each other decreases, a reflection of the light at an interface between the layers that may be in contact with each other may be reduced. As a result, the transmittance of the light passing through a transmission area may be improved. However, this is merely an example, and each of the first and second sub-barrier layers BR1 and BR2 may include various materials.

The light blocking layer BML may be disposed on the barrier layer BR. The light blocking layer BML may include molybdenum (Mo), an alloy including molybdenum (Mo), silver (Ag), an alloy including silver (Ag), aluminum (Al), an alloy including aluminum (Al), aluminum nitride (AlN), tungsten (W), tungsten nitride (WN), copper (Cu), titanium Ti, p+ doped amorphous silicon, MoTaOx, or the like, or a combination thereof, however, embodiments are not limited thereto or thereby. The light blocking layer BML may be referred to as a rear surface metal layer or a rear surface layer.

The light blocking layer BML may include a first light blocking layer BMLa and a second light blocking layer BMLb, which may be disposed on different layers from each other. The first light blocking layer BMLa and the second light blocking layer BMLb may respectively block a light incident into the first and second thin film transistors S-TFT and O-TFT from a rear surface of the substrate 110. Accordingly, defects in which characteristics of the first and second thin film transistors S-TFT and O-TFT are deformed or noise signals are generated by the light may be prevented.

The first light blocking layer BMLa may be disposed on the first sub-barrier layer BR1 and may be disposed in the second sub-barrier layer BR2. For example, the first light blocking layer BMLa may be formed after a portion of the second sub-barrier layer BR2 in a thickness direction is formed, and another portion of the second sub-barrier layer BR2 in the thickness direction may be formed to cover the first light blocking layer BMLa. However, this is merely an example, the first light blocking layer BMLa may be disposed under or above the second sub-barrier layer BR2 as long as the first light blocking layer BMLa is disposed under the first thin film transistor S-TFT, and embodiments are not particularly limited.

The buffer layer BF may be disposed on the barrier layer BR. The buffer layer BF may prevent metal atoms or impurities from being diffused to a first semiconductor pattern of the first thin film transistor S-TFT from the substrate 110. The buffer layer BF may control a rate of heat supply during a crystallization process to form the first semiconductor pattern so that the first semiconductor pattern of the first thin film transistor S-TFT may be uniformly formed.

The buffer layer BF may include a first sub-buffer layer BF1 and a second sub-buffer layer BF2 disposed on the first sub-buffer layer BF1. Each of the first sub-buffer layer BF1 and the second sub-buffer layer BF2 may include at least one of silicon oxide, silicon nitride, and silicon oxynitride. As an example, the first sub-buffer layer BF1 may include silicon nitride, and the second sub-buffer layer BF2 may include silicon oxide.

Although not shown in figures, a portion of the second sub-buffer layer BF2 may be removed in a certain area (for example, transmission area). Accordingly, a thickness of a portion of the second sub-buffer layer BF2 can be different in a different area. However, this is merely an example, the second sub-buffer layer BF2 may have a unform thickness in all of the area of the display panel and embodiments are not particularly limited.

The insulating layers 10 to 80 may include multiple inorganic insulating layers. According to an embodiment, at least some layers among the first insulating layer 10 to fifth insulating layer 50 sequentially disposed on the buffer layer BF may be an inorganic insulating layer. As an example, all of the first insulating layer 10 to fifth insulating layer 50 may be the inorganic insulating layer.

The first thin film transistor S-TFT may be disposed on the buffer layer BF. The first thin film transistor S-TFT may include a first gate GT1, a first source SE1, a first drain DE1, and a first channel AC1. The first source SE1, the first drain DE1, and the first channel AC1 may form a single semiconductor pattern (hereinafter, referred to as the first semiconductor pattern).

The first semiconductor pattern may be disposed on the buffer layer BF. The first semiconductor pattern may include a silicon semiconductor. As an example, the silicon semiconductor may include amorphous silicon or polycrystalline silicon. For example, the first semiconductor pattern may include low temperature polycrystalline silicon.

FIG. 3B shows only a portion of the first semiconductor pattern disposed on the buffer layer BF, and the first semiconductor pattern may be further disposed in other areas. The first semiconductor pattern may be arranged with a specific rule over the pixels. The first semiconductor pattern may have different electrical properties depending on whether it is doped or not or whether it is doped with an N-type dopant or a P-type dopant. The first semiconductor pattern may include a first region having a relatively high conductivity and a second region having a relatively low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped at a concentration lower than that of the first region.

The first region may have a conductivity greater than that of the second region and may be a source area or a drain area of the first thin film transistor S-TFT or may substantially serve as an electrode or a signal line. The second region may substantially correspond to an active area (or a channel) of the first thin film transistor S-TFT.

In an embodiment, each of the first source SE1 and the first drain DE1 may be the first region, and the first channel AC1 may be the second region. However, this is merely an example, the first source SE1 and the first drain DE1 may be provided as electrodes separated from the first channel AC1 and may be connected to the first semiconductor pattern, and embodiments are not limited thereto or thereby.

The first gate GT1 may be disposed on the first insulating layer 10. The first gate GT1 may be a portion of a metal pattern. The first gate GT1 may overlap the first channel AC1. The first gate GT1 may be used as a mask in a process of doping the first semiconductor pattern. The first gate GT1 may include titanium (Ti), silver (Ag), an alloy including silver (Ag), molybdenum (Mo), an alloy including molybdenum (Mo), aluminum (Al), an alloy including aluminum (Al), aluminum nitride (AlN), tungsten (W), tungsten nitride (WN), copper (Cu), indium tin oxide (ITO), indium zinc oxide (IZO), or the like, or a combination thereof, however, embodiments are not particularly limited.

The second insulating layer 20 may be disposed on the first insulating layer 10 and may cover the first gate GT1. The second insulating layer 20 may be an inorganic layer and may have a single-layer or multi-layer structure. The second insulating layer 20 may include at least one of silicon oxide, silicon nitride, and silicon oxynitride. According to an embodiment, the second insulating layer 20 may have the multi-layer structure of a silicon oxide layer and a silicon nitride layer.

The third insulating layer 30 may be disposed on the second insulating layer 20. The third insulating layer 30 may be an inorganic layer and may have a single-layer or multi-layer structure. As an example, the third insulating layer 30 may have the multi-layer structure of a silicon oxide layer and a silicon nitride layer. A second electrode CE2 of the capacitor Cst may be disposed between the second insulating layer 20 and the third insulating layer 30. A first electrode CE1 of the capacitor Cst may be disposed between the first insulating layer 10 and the second insulating layer 20.

The second light blocking layer BMLb may be disposed on the second insulating layer 20 and may be covered by the third insulating layer 30. The second light blocking layer BMLb may be disposed on the same layer as the second electrode CE2 and may be substantially simultaneously formed with the second electrode CE2 through the same process. Accordingly, a process cost may be reduced, and a manufacturing process may be simplified. However, this is merely an example, the second light blocking layer BMLb may be disposed on a different layer from a layer on which the second electrode CE2 is disposed or may be formed of a different material from the second electrode CE2, and embodiments are not particularly limited.

The second thin film transistor O-TFT may be disposed on the third insulating layer 30. The second thin film transistor O-TFT may include a second gate GT2, a second source SE2, a second drain DE2, and a second channel AC2. The second source SE2, the second drain DE2, and the second channel AC2 may form a single semiconductor pattern (hereinafter, referred to as a second semiconductor pattern).

The second semiconductor pattern may be disposed on the third insulating layer 30. The second semiconductor pattern may include an oxide semiconductor. The oxide semiconductor may include multiple areas distinguished from each other depending on whether a metal oxide is reduced. The area (hereinafter, referred to as a reduced area) in which the metal oxide may be reduced has a conductivity greater than that of the area (hereinafter, referred to as a non-reduced area) in which the metal oxide is not reduced.

The reduced area may act as a source area or a drain area of the second thin film transistor O-TFT or may substantially serve as an electrode or a signal line. The non-reduced area may correspond to the active area (or a channel) of the second thin film transistor O-TF T.

In an embodiment, each of the second source SE2 and the second drain DE2 may be the reduced area, and the second channel AC2 may be the non-reduced area, however, this is merely an example. According to an embodiment, the second source SE2 and the second drain DE2 may be provided as electrodes separated from the second channel AC2 and may be connected to the second semiconductor pattern, and embodiments are not particularly limited.

The fourth insulating layer 40 may be disposed on the third insulating layer 30. The fourth insulating layer 40 may commonly overlap the pixels and may cover the second semiconductor pattern. The fourth insulating layer 40 may be an inorganic layer and may have a single-layer or multi-layer structure. The fourth insulating layer 40 may include at least one of aluminum oxide, titanium oxide, silicon oxide, silicon nitride, silicon oxynitride, zirconium oxide, and hafnium oxide.

The second gate GT2 may be disposed on the fourth insulating layer 40. The second gate GT2 may be a portion of a metal pattern. The second gate GT2 may overlap the second channel AC2 in a plan view. The second gate GT2 may be used as a mask in a process of doping the second semiconductor pattern.

The fifth insulating layer 50 may be disposed on the fourth insulating layer 40 and may cover the second gate GT2. The fifth insulating layer 50 may be an inorganic layer and/or an organic layer and may have a single-layer or multi-layer structure.

A first connection electrode CNE1 may be disposed on the fifth insulating layer 50. The first connection electrode CNE1 may be connected to the first drain DE1 via a contact hole defined through the first, second, third, fourth, and fifth insulating layers 10, 20, 30, 40, and 50. Although not shown in FIG. 3B, the display panel DP may further include a connection electrode formed at a position corresponding to the first connection electrode CNE1 and connected to the second drain DE2 or the second source SE2, however, embodiments are not particularly limited.

In an embodiment, the first thin film transistor S-TFT is described as the silicon thin film transistor, and the second thin film transistor O-TFT is described as the oxide thin film transistor. However, according to an embodiment, the first thin film transistor S-TFT may be the oxide thin film transistor, and the second thin film transistor O-TFT may be the silicon thin film transistor. According to an embodiment, the first and second thin film transistors S-TFT and O-TFT may be formed of the same semiconductor material. According to an embodiment, the pixel circuit PC may be designed with various thin film transistors and is not particularly limited.

The circuit layer 120 may include organic insulating layers disposed on the inorganic insulating layers. As an example, at least one of the sixth, seventh, and eighth insulating layers 60, 70, and 80 may be an organic insulating layer.

The sixth insulating layer 60 may be disposed on the fifth insulating layer 50. The sixth insulating layer 60 may include an organic material. For example, the sixth insulating layer 60 may include a polyimide-based resin. A second connection electrode CNE2 may be disposed on the sixth insulating layer 60. The second connection electrode CNE2 may be connected to the first connection electrode CNE1 through a contact hole defined through the sixth insulating layer 60.

The seventh insulating layer 70 may be disposed on the sixth insulating layer 60 and may cover the second connection electrode CNE2. The eighth insulating layer 80 may be disposed on the seventh insulating layer 70.

Each of the sixth insulating layer 60, the seventh insulating layer 70, and the eighth insulating layer 80 may be an organic layer. In the disclosure, the sixth insulating layer 60 may be referred to as a first organic insulating layer, the seventh insulating layer 70 may be referred to as a second organic insulating layer, and the eighth insulating layer 80 may be referred to as a third organic insulating layer. As an example, each of the sixth insulating layer 60, the seventh insulating layer 70, and the eighth insulating layer 80 may include a general-purpose polymer, such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, and a fluorine-based polymer, a p-xylene-based polymer, a vinyl alcohol-based polymer, or blends thereof.

At least some insulating layers of the buffer layer BF, the barrier layer BR, and the insulating layers 10, 20, 30, 40, 50, 60, 70, and 80, which may be included in the circuit layer 120, may be provided with an opening defined therethrough to overlap the transmission area. According to the disclosure, the insulating layers in a certain area may be removed, and thus, a transmittance of the certain area may increase, however, this is merely an example. According to an embodiment, all the buffer layer BF, the barrier layer BR, and the insulating layers 10, 20, 30, 40, 50, 60, 70, and 80 may be formed on all of the area of the display panel without the opening (different from a contact hole) and are not particularly limited.

The light emitting element layer 130 including the light emitting element LD may be disposed on the circuit layer 120. The light emitting element LD may include a pixel electrode AE, a first functional layer HFL, a light emitting layer EL, a second functional layer EFL, and a common electrode CE. Each of the first functional layer HFL, the second functional layer EFL, and the common electrode CE may be provided in an integral shape over the display panel. However, this is merely an example. The first functional layer HFL, the second functional layer EFL, and the common electrode CE may be patterned in every pixel PX, and embodiments are not particularly limited.

The pixel electrode AE may be disposed on the eighth insulating layer 80. The pixel electrode AE1 may be a semi-transmissive electrode, a transmissive electrode, or a reflective electrode. According to an embodiment, the pixel electrode AE may include a reflective layer formed of Ag, Mg, Al, Pt, Pd, Au, Ni, Nd, Ir, Cr, or compounds thereof, or a combination thereof, and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For instance, the pixel electrode AE may have a stack structure of ITO/Ag/ITO.

In an embodiment, the pixel electrode AE may be connected to the first thin film transistor S-TFT via the first connection electrode CNE1 and the second connection electrode CNE2, however, this is merely an example. According to an embodiment, the pixel electrode AE may be connected to the second thin film transistor O-TFT and are not particularly limited.

A pixel definition layer PDL may be disposed on the eighth insulating layer 80. The pixel definition layer PDL may have a light absorbing property, for example, the pixel definition layer PDL may have a black color. The pixel definition layer PDL may include a black coloring agent. The black coloring agent may include a black dye or a black pigment. The black coloring agent may include a metal material, such as carbon black, chromium, an oxide thereof, or a combination thereof.

The pixel definition layer PDL may be provided with an opening PDL-OP (hereinafter, referred to as a light emitting opening) defined therethrough to expose a portion of the pixel electrode AE. For example, the pixel definition layer PDL may cover an edge of the pixel electrode AE.

The first functional layer HFL may be disposed on the pixel electrode AE and the pixel definition layer PDL. The first functional layer HFL may include a hole transport layer, may include a hole injection layer, or may include both the hole transport layer and the hole injection layer.

The light emitting layer EL may be disposed on the first functional layer HFL and may be disposed in an area corresponding to the light emitting opening PDL-OP of the pixel definition layer PDL. The light emitting layer EL may include an organic material, an inorganic material, or an organic-inorganic material, which emits a light having a color.

The second functional layer EFL may be disposed on the first functional layer HFL and may cover the light emitting layer EL. The second functional layer EFL may include an electron transport layer, may include an electron injection layer, or may include both the electron transport layer and the electron injection layer.

The common electrode CE may be disposed on the second functional layer EFL. The common electrode CE may be formed of a transmissive electrode layer or a semi-transmissive electrode layer. As an example, the common electrode CE may include a thin layer, e.g., an Ag layer, with a light transmittance.

Although not shown in figures, the light emitting element layer 130 may further include a capping layer disposed on the common electrode CE. The capping layer may include LiF, an inorganic material, and/or an organic material. The capping layer CPL may protect the common electrode CE in a process of forming the encapsulation layer 140 and may improve a light extraction efficiency of the light emitting element LD through a refractive index matching with the common electrode CE.

The encapsulation layer 140 may be disposed on the light emitting element layer 130. The encapsulation layer 140 may include an inorganic layer 141, an organic layer 142, and an inorganic layer 143, which may be sequentially stacked on each other, however, layers included in the encapsulation layer 140 are not limited thereto or thereby.

The inorganic layers 141 and 143 may protect the light emitting element layer 130 from moisture and oxygen, and the organic layer 142 may protect the light emitting element layer 130 from a foreign substance such as dust particles. The inorganic layers 141 and 143 may include a silicon nitride layer, a silicon oxynitride layer, a silicon oxide layer, a titanium oxide layer, or an aluminum oxide layer, or a combination thereof. The organic layer 142 may include an acrylic-based organic layer, however, embodiments are not limited thereto or thereby.

The sensor layer 200 may be disposed on the display layer 100. The sensor layer 200 may sense an external input applied thereto from the outside. The external input may be a user input. The user input may include a variety of external inputs, such as a part of a user's body, light, heat, pen, or pressure. The sensor layer 200 may be referred to as a sensor, an input sensing layer, or an input sensing panel.

The sensor layer 200 may include a sensor base layer 210, a first sensor conductive layer 220, a sensor insulating layer 230, a second sensor conductive layer 240, and a sensor cover layer 250. The sensor base layer 210 may be disposed directly on the display layer 100. The sensor base layer 210 may be an inorganic layer including at least one of silicon nitride, silicon oxynitride, and silicon oxide. According to an embodiment, the sensor base layer 210 may be an organic layer including an epoxy resin, an acrylic resin, or an imide-based resin. The sensor base layer 210 may have a single-layer structure or a multi-layer structure of layers stacked on each other in the third directional axis DR3.

Each of the first sensor conductive layer 220 and the second sensor conductive layer 240 may have a single-layer structure or a multi-layer structure of layers stacked on each other in the third directional axis DR3.

The conductive layer having the single-layer structure may include a metal layer or a transparent conductive layer. The metal layer may include molybdenum, silver, titanium, copper, aluminum, or alloys thereof, or a combination thereof. The transparent conductive layer may include a transparent conductive oxide, such as indium tin oxide (ITO), indium zinc oxide (IZO), zinc oxide (ZnO), indium zinc tin oxide (ITZO), or the like, or a combination thereof. The transparent conductive layer may include conductive polymer such as PEDOT, metal nanowire, graphene, or the like, or a combination thereof.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensor insulating layer 230 may be disposed between the first sensor conductive layer 220 and the second sensor conductive layer 240. The sensor insulating layer 230 may include an inorganic layer. The inorganic layer may include at least one of aluminum oxide, titanium oxide, silicon oxide, silicon nitride, silicon oxynitride, zirconium oxide, and hafnium oxide.

According to an embodiment, the sensor insulating layer 230 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The sensor cover layer 250 may be disposed on the sensor insulating layer 230 and may cover the second sensor conductive layer 240. The second sensor conductive layer 240 may include a conductive pattern 240P. The sensor cover layer 250 may cover the second sensor conductive layer 240 and may reduce a possibility of occurrence of damages in the second sensor conductive layer 240 in the subsequent process.

The sensor cover layer 250 may include an inorganic material. As an example, the sensor cover layer 250 may include silicon nitride, however, embodiments are not limited thereto or thereby.

The anti-reflective layer 300 may be disposed on the sensor layer 200. The anti-reflective layer 300 may reduce a reflectance with respect to an external light incident thereto from the outside. The anti-reflective layer 300 may selectively transmit the light emitted from the display layer 100. The anti-reflective layer 300 may include a division layer 310, color filters 320, and a planarization layer 330.

The division layer 310 may be disposed to overlap the second sensor conductive layer 240. In an embodiment, the conductive pattern 240P may correspond to the second sensor conductive layer 240. The sensor cover layer 250 may be disposed between the division layer 310 and the second sensor conductive layer 240. The division layer 310 may prevent the external light from being reflected by the second sensor conductive layer 240. Materials for the division layer 310 are not particularly limited as long as the materials absorb a light.

The division layer 310 may have a black color and may have a black coloring agent. The black coloring agent may include a black dye or a black pigment. The black coloring agent may include a metal material, such as carbon black, chromium, an oxide thereof, or a combination thereof.

The division layer 310 may be provided with division openings 310-OP defined therethrough. Each of the division openings 310-OP may overlap the light emitting layer EL, respectively. The color filters 320 may be disposed to correspond to the division openings 310-OP, respectively. The color filter 320 may transmit a light provided from the light emitting layer EL overlapping the color filter 320.

The planarization layer 330 may cover the division layer 310 and the color filters 320. The planarization layer 330 may include an organic material and may provide a flat surface on an upper surface thereof. According to an embodiment, the planarization layer 330 may be omitted.

According to an embodiment, the anti-reflective layer 300 may have a single-layer structure that includes a base resin and a dye and/or a pigment dispersed in the base resin. For example, the color filters 320 may be changed to a dye/pigment layer. The anti-reflective layer 300 may be provided as a single layer overlapping all of the light emitting elements LD.

According to an embodiment, at least one of the sensor layer 200 and the anti-reflective layer 300 may be omitted in the display panel DP, and the display panel DP is not particularly limited.

Referring to FIG. 3D, the display panel DP-Q may further include an optical structure layer OSL. The display panel DP-Q may include a display layer 100-1, the optical structure layer OSL, and a filling layer FML.

The display layer 100-1 may include a substrate 110-1, a circuit layer 120-1, a light emitting element layer 130-1, and an encapsulation layer 140. The substrate 110-1 may have a single-layer structure. As an example, the substrate 110-1 may be a glass substrate, a metal substrate, or a polymer substrate.

The circuit layer 120-1 may have a layer structure different from that of the circuit layer 120 shown in FIG. 3C. As an example, the circuit layer 120-1 may include a thin film transistor T-D, a lower buffer layer BRL, and first, second, and third insulating layers 11, 21, and 31. FIG. 3D shows an arrangement of an active area A-D, a source area S-D, a drain area D-D, and a gate G-D, which form the thin film transistor T-D, as a representative example. The active area A-D, the source area S-D, and the drain area D-D may be distinguished from each other according to a doping concentration or a conductivity of a semiconductor pattern.

The lower buffer layer BRL and the first, second, and third insulating layers 11, 21, and 31 may be sequentially arranged in the upward direction D3U, and each of the active area A-D, the source area S-D, the drain area D-D, and the gate G-D may be disposed between the insulating layers BRL, 11, 21, and 31. As an example, the lower buffer layer BRL, and the first and second insulating layers 11 and 21 may be an inorganic layer, and the third insulating layer 31 may be an organic layer.

The light emitting element layer 130-1 may include a light emitting element LED. The light emitting element LED may correspond to the above-described light emitting element LD. In detail, the light emitting element LED may include a first electrode EL1, a second electrode EL2, and a light emitting layer EML disposed between the first electrode EL1 and the second electrode EL2. A hole control layer HTR and an electron control layer ETR may be disposed between the first electrode EL1 and the light emitting layer EML and between the light emitting layer EML and the second electrode EL2, respectively.

The light emitting layer EML may have a single-layer structure different from the light emitting layer EL shown in FIG. 3C, however, embodiments are not limited thereto or thereby. The light emitting layer EML may generate a light as a source light. The light emitting layer EML may generate a blue light. The blue light may have a wavelength from about 410 nm to about 480 nm. A light emission spectrum of the blue light may have a maximum peak within a wavelength range from about 440 nm to about 460 nm.

The encapsulation layer 140 may be disposed on the light emitting element layer 130-1. The optical structure layer OSL may be disposed on the thin film encapsulation layer 140. The optical structure layer OSL may include a light control layer CCL, a color filter layer CFL, and a base layer BL. In the disclosure, the optical structure layer OSL may be referred to as an upper panel, an upper display substrate, or an optical member.

The light control layer CCL may be disposed on the display layer 100-1 including the light emitting element LED. The light control layer CCL may include a bank BMP, a light control pattern CCP, and barrier layers CAP and CAP-T.

The bank BMP may include a base resin and additives. The base resin may include various resin compositions that are generally referred to as a binder. The additives may include coupling agents and/or photoinitiators. The additives may further include a dispersant.

The bank BMP may include a black coloring agent to block a light. The bank BMP may include a black dye or a black pigment mixed with the base resin. According to an embodiment, the black coloring agent may include a metal material, such as carbon black, chromium, an oxide thereof, or a combination thereof.

The bank BMP may be provided with a bank opening BW-OH defined therethrough and corresponding to a light emitting opening OH. The bank opening BW-OH may overlap the light emitting opening OH in a plan view and may have a size greater than that of the light emitting opening OH. For example, the bank opening BW-OH may have a size greater than that of a light emitting area EA1 defined by the light emitting opening OH. In the disclosure, the expression “two components correspond to each other” means that the two components may overlap each other, however, the expression should not be restricted to mean that the two components have the same size.

The light control patterns CCP may be disposed inside the bank opening BW-OH. At least a light control pattern CCP-R of the light control patterns CCP may convert optical properties of the source light.

The light control pattern CCP-R may include a quantum dot to convert the optical properties of the source light. The light control pattern CCP-R may include the quantum dot to convert the source light to a light having another wavelength. The quantum dot included in the light control pattern CCP-R overlapping a first pixel area PXA-R may convert the blue light that is the source light into a red light.

The quantum dot may have a core-shell structure, and a core of the quantum dot may be selected from a group II-VI compound, a group III-VI compound, a group compound, a group III-V compound, a group IV-VI compound, a group IV element, a group IV compound, and a combination thereof.

The group II-VI compound may be selected from a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound of In₂S₃ or In₂Se₃, a ternary compound of InGaS₃ or InGaSe₃, or an arbitrary combination thereof.

The group compound may include a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound of AgInGaS₂, CuInGaS₂, or the like, or a combination thereof.

The group III-V compound may be selected from a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AINAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The group III-V compound may further include a group II metal. For instance, InZnP may be selected as a group III-II-V compound.

The group IV-VI compound may be selected from a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

The binary compound, the ternary compound, or the quaternary compound may exist in the particles at a uniform concentration or may exist in the same particle after being divided into multiple portions having different concentrations. The quantum dots may have a core/shell structure in which one quantum dot surrounds another quantum dot. In the core/shell structure, the concentration of elements existing in the shell may have a concentration gradient that is lowered as the distance from the core decreases.

The quantum dot may have a core-shell structure that includes a core having a nanocrystal and a shell surrounding the core. The shell of the quantum dot may serve as a protective layer to prevent chemical modification of the core and to maintain semiconductor properties and/or may serve as a charging layer to impart electrophoretic properties to the quantum dot. The shell may have a single-layer or multi-layer structure. The shell of the quantum dots may include metal oxides or non-metal oxides, semiconductor compounds, or combinations thereof as its representative example.

The metal oxides or non-metal oxides may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound, such as MgAl₂O₄, CoFe₂O₄, NiFe₂O₄, and CoMn₂O₄, however, embodiments are not limited thereto or thereby.

The semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, however, embodiments are not limited thereto or thereby.

The quantum dots may have a full width of half maximum (FWHM) of the light emission wavelength spectrum of about 45 nm or less, in an embodiment about 40 nm or less, and in another embodiment about 30 nm or less. The color purity and the color reproducibility may be improved within this range. Since the light emitted through the quantum dots may be emitted in all directions, an optical viewing angle may be improved.

The shape of the quantum dots may have a shape commonly used in the art, however, embodiments are not particularly limited. In more detail, spherical, pyramidal, multi-arm, or cubic nanoparticles, nanotubes, nanowires, nanofibers, nanoplatelets, or the like may be applied to the quantum dots.

The quantum dots may control the color of the emitted light depending on a particle size thereof, and accordingly, the quantum dots may have various emission colors such as blue, red, and green colors. According to an embodiment, the quantum dot included in the light control pattern CCP-R overlapping the first pixel area PXA-R may have a red emission color. As the particle size of the quantum dots decreases, the wavelength of the light emitted from the quantum dots becomes shorter. For example, the particle size of the quantum dots emitting a green light may be smaller than the particle size of the quantum dots emitting the red light in the quantum dots having the same core. The particle size of the quantum dots emitting the blue light may be smaller than the particle size of the quantum dots emitting the green light in the quantum dots having the same core. However, the disclosure is not limited thereto or thereby, and in the quantum dots having the same core, the particle size may be adjusted depending on a material for the shell and a thickness of the shell.

In the case where the quantum dots have various emission colors such as blue, red, green, etc., materials for cores of the quantum dots having different emission colors may be different from each other.

The light control pattern CCP-R may further include a scatterer. The light control pattern CCP-R may include the quantum dot converting the source light to the red light and the scatterer scattering the light.

The scatterer may be an inorganic particle. As an example, the scatterer may include at least one of TiO₂, ZnO, Al₂O₃, SiO₂, and a hollow silica. The scatterer may include at least one of TiO₂, ZnO, Al₂O₃, SiO₂, and the hollow silica or may include a mixed material of two or more of TiO₂, ZnO, Al₂O₃, SiO₂, and the hollow silica.

The light control pattern CCP-R may include a base resin in which the quantum dot and the scatterer may be dispersed. The base resin may be a medium in which the quantum dot and the scatterer may be dispersed, and may include various resin compositions that are generally referred to as a binder. As an example, the base resin may be an acrylic-based resin, a urethane-based resin, a silicone-based resin, an epoxy-based resin, or a combination thereof. The base resin may be a transparent resin.

In an embodiment, the light control pattern CCP-R may be formed by an inkjet process. A liquid composition may be provided within the bank opening BW-OH. The composition that may be polymerized by a thermal curing process or a light curing process may be reduced in volume after curing.

A step difference may occur between an lower surface of the bank BMP and an lower surface of the light control pattern CCP-R. For example, the lower surface of the bank BMP may be defined at a position lower than the lower surface of the light control pattern CCP-R. A difference in height between the lower surface of the bank BMP and the lower surface of the light control pattern CCP-R may be within a range from about 2 μm to about 3 μm.

The light control layer CCL may include barrier layers CAP and CAP-T disposed on at least one of upper and lower surfaces of the light control pattern CCP-R. The barrier layers CAP and CAP-T may prevent moisture and/or oxygen (hereinafter, referred to as moisture/oxygen) from entering. The barrier layers CAP and CAP-T may be disposed on and under the light control pattern CCP-R to prevent the light control patterns CCP-R, CCP-B from being exposed to the moisture/oxygen.

The barrier layers may include a first barrier layer CAP adjacent to the display layer 100-1 and a second barrier layer CAP-T spaced apart from the display layer 100-1 with the light control pattern CCP-R interposed therebetween. The first barrier layer CAP may cover a surface of the light control pattern CCP-R adjacent to the display layer 100-1, and the second barrier layer CAP-T may cover another surface of the light control pattern CCP-R adjacent to the color filter layer CFL. The barrier layers CAP and CAP-T may cover the bank BMP as well as the light control pattern CCP-R.

The first barrier layer CAP may be disposed corresponding to a step difference between the bank BMP and the light control pattern CCP-R. The second barrier layer CAP-T may cover a surface of each of the bank BMP and the light control pattern CCP-R, which may be adjacent to the color filter layer CFL. The second barrier layer CAP-T may be disposed directly on a low refractive layer LR.

The barrier layers CAP and CAP-T may include at least one inorganic layer. For example, the barrier layers CAP and CAP-T may include an inorganic material. As an example, the barrier layers CAP and CAP-T may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, and a metal thin film having light transmittance. As an example, the first barrier layer CAP disposed under the light control pattern CCP-R may include silicon oxynitride, and the second barrier layer CAP-T disposed on the light control pattern CCP-R may include silicon oxide, however, embodiments are not limited thereto or thereby. The barrier layers CAP and CAP-T may further include an organic layer. The barrier layers CAP and CAP-T may have a single-layer or multi-layer structure. In the barrier layers CAP and CAP-T, the inorganic layer may prevent the light control pattern CCP-R from external moisture, and the organic layer may compensate for the step difference between the bank BMP and the light control pattern CCP-R and may provide a flat base surface for members disposed thereon.

The color filter layer CFL may be disposed on the light control layer CCL. The color filter layer CFL may include at least one color filter CF1. The color filter CF1 may transmit a light in a specific wavelength range and may block a light outside the specific wavelength range. The color filter CF1 of the first pixel area PXA-R may transmit red light and may block green light and blue light.

The color filter CF1 may include a base resin and a dye and/or a pigment dispersed in the base resin. The base resin may be a medium in which the dye and/or the pigment may be dispersed and may include various resin compositions that are generally referred to as a binder. Hereinafter, the color filter CF1 is described in detail.

The color filter CF1 may have a uniform thickness in the first pixel area PXA-R. The red light obtained by converting the source light including the blue light through the light control pattern CCP-R may be provided to the outside at a uniform luminance in the first pixel area PXA-R.

The color filter layer CFL may include the low refractive layer LR. The low refractive layer LR may be disposed between the light control layer CCL and the color filter CF1. The low refractive layer LR may be disposed on the light control layer CCL to prevent the light control pattern CCP-R from being exposed to moisture/oxygen. The low refractive layer LR may be disposed between the light control pattern CCP-R and the color filter CF1 to serve as an optical functional layer that increases a light extraction efficiency or that prevents a reflected light from entering the light control layer CCL. The low refractive layer LR may have a refractive index smaller than that of layers adjacent thereto.

The low refractive layer LR may have a relatively low refractive index and may be a mixed layer of an organic material and an inorganic material. According to an embodiment, the low refractive layer LR may include a polymer resin and may be obtained by dispersing inorganic particles in the polymer resin. The polymer resin included in the low refractive layer LR may be, for example, a silicon resin and/or an acryl silicon resin. The inorganic particles included in the low refractive layer LR may be, for example, hollow silica and/or porogen, however, embodiments are not limited thereto or thereby. According to an embodiment, the low refractive layer LR may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, and a metal thin film having the light transmittance. The low refractive layer LR may have a single-layer or multi-layer structure.

The low refractive layer LR may have the refractive index equal to or smaller than about 1.3. According to an embodiment, the refractive index of the low refractive layer LR may be about 1.2. The low refractive layer LR may have the refractive index of 1.3 or less in a wavelength range of about 400 nm or more and about 700 nm or less, which is a visible light range.

The color filter CF1 of the color filter layer CFL may be disposed directly on the light control layer CCL in the display device DD. The low refractive layer LR may be omitted.

According to an embodiment, the display panel DP-Q may further include a base layer BL disposed on the color filter layer CFL. The base layer BL may provide a base surface on which the color filter layer CFL and the light control layer CCL may be disposed. The base layer BL may be a glass substrate, a metal substrate, or a plastic substrate, however, embodiments are not limited thereto or thereby. According to an embodiment, the base layer BL may be an inorganic layer, an organic layer, or a composite material layer. According to an embodiment, the base layer BL may be omitted. Although not shown in figures, a layer may be disposed on the base layer BL to prevent a light from being reflected, and the anti-reflective layer 300 shown in FIG. 3C or an anti-reflective layer formed of a continuous layer may be disposed on the base layer BL.

The display panel DP-Q may include a lower panel including the display layer 100-1 and the upper panel (e.g., the optical structure layer OSL) including the light control layer CCL and the color filter layer CFL, and the filling layer FML may be disposed between the lower panel and the upper panel OSL. According to an embodiment, the filling layer FML may be filled in between the display layer 100-1 and the light control layer CCL. The filling layer FML may be disposed directly on the encapsulation layer 140, and the first barrier layer CAP included in the light control layer CCL may be disposed directly on the filling layer FML. A lower surface of the filling layer FML may be in contact with an upper surface of the encapsulation layer 140, and an upper surface of the filling layer FML may be in contact with a lower surface of the barrier layer CAP.

The filling layer FML may function as a buffer between the display layer 100-1 and the light control layer CCL. According to an embodiment, the filling layer FML may have an impact absorbing function and may increase a strength of the display panel DP-Q. The filling layer FML may be formed of a filling resin including a polymer resin. As an example, the filling layer FML may be formed of the filling resin, such as an acrylic-based resin or an epoxy-based resin.

The filling layer FML may be formed through a separate process from the encapsulation layer 140 disposed thereunder and the first barrier layer CAP disposed thereon. The filling layer FML may be formed of a material different from those of the encapsulation layer 140 and the first barrier layer CAP.

Referring to FIGS. 2, 3A, and 3B again, as an example, the deposition chamber DPA may be used in the deposition process of forming the first functional layer HFL, the second functional layer EFL, or the common electrode CE. According to an embodiment, the deposition chamber DPA may be used in the deposition process of forming the insulating layers 10 to 80 of the circuit layer 120 or the inorganic layers 141 and 143 of the encapsulation layer 140.

A fixing member CM may be disposed in the deposition chamber DPA, may be disposed on a deposition source DS, and may fix the mask MSK. The fixing member CM may be installed at the ceiling surface of the deposition chamber DPA. The fixing member CM may include a jig or a robot arm to hold the mask MSK.

The fixing member CM may include a body portion BD and magnetic substances MM coupled to the body portion BD. The body portion BD may include a plate as a basic structure to fix the mask MSK, however, embodiments are not particularly limited. The magnetic substances MM may be disposed inside or outside of the body portion BD. The magnetic substances MM may fix the mask MSK using a magnetic force.

The deposition source DS may evaporate a deposition material, e.g., an organic material, an inorganic material, a metal material, etc., and may spray the evaporated deposition material as a vapor. The sprayed deposition material may be deposited on the work substrate WS in a pattern after passing through the mask MSK. As described above, the work substrate WS may correspond to substrates in a variety of stages in the manufacturing process of the display panel DP.

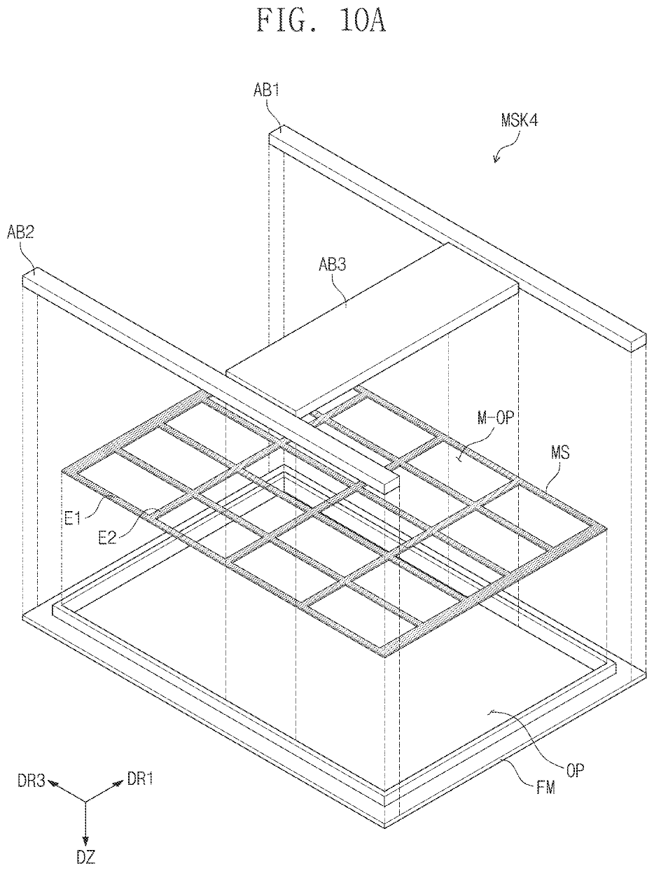

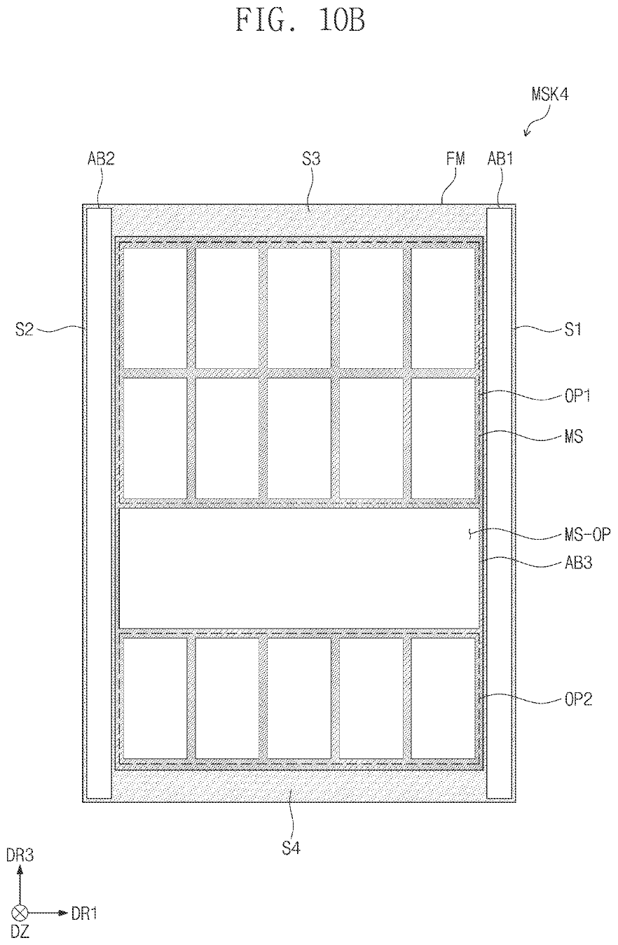

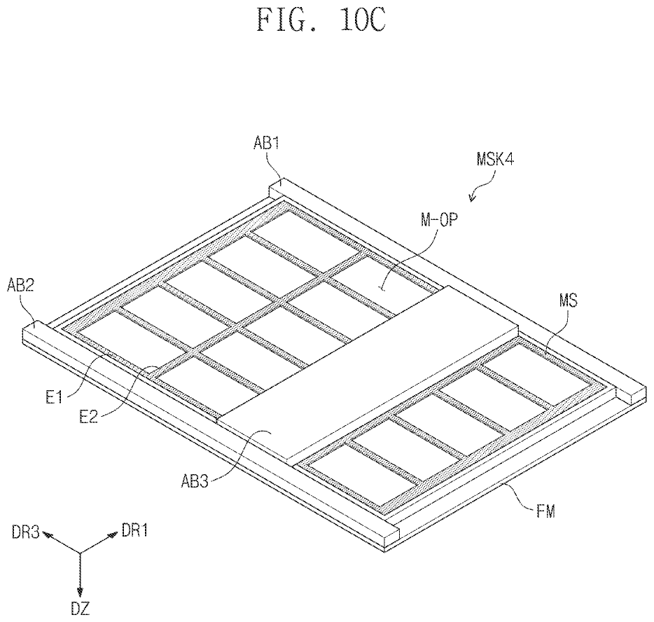

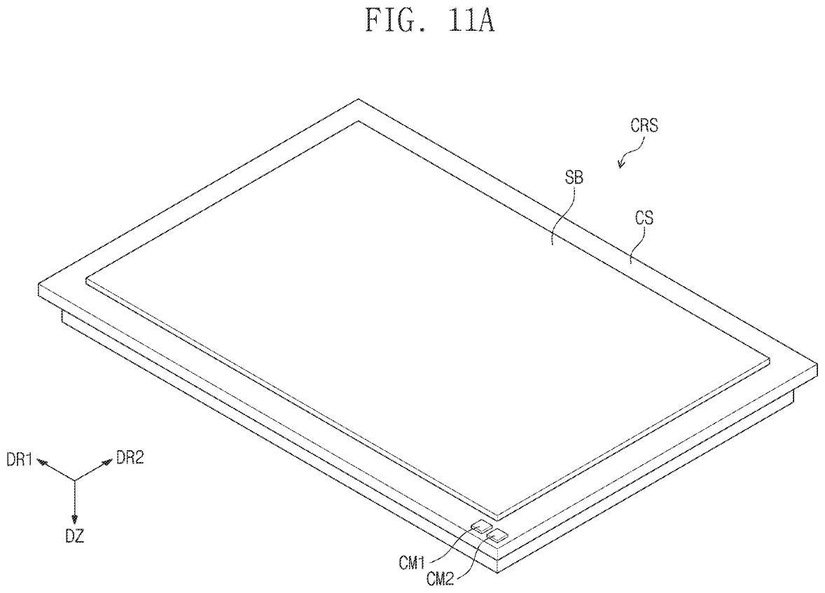

The mask MSK may be disposed inside the deposition chamber DPA, may be disposed above the deposition source DS, and may support the work substrate WS. In an embodiment, the mask MSK may include a frame FM and a stick ST. The stick ST may correspond to a mask sheet MS (refer to FIG. 10A), and an opening defined by the frame FM may be further subdivided by the stick ST. Accordingly, the stick ST may be omitted in the mask MSK. Although not shown in figures, an additional support member may be further disposed in the deposition chamber DPA to fix the mask MSK, however, the disclosure is not limited thereto or thereby.

FIG. 3A shows a work substrate WS1 (hereinafter, referred to as a work substrate before deposition) provided in the deposition chamber DPA, and FIG. 3B shows a work substrate WS2 (hereinafter, referred to as a work substrate after deposition) after the deposition process is performed on the work substrate in the deposition chamber DP. For convenience of explanation, the substrate 110 and the circuit layer 120 are illustrated in a simplified form.

In an embodiment, the deposition chamber DPA may be an apparatus to perform the deposition process on the first functional layer HFL. Accordingly, the work substrate before deposition WS1 may be in a state in which multiple pixel electrodes AE-R, AE-G, AE-B and the pixel definition layer PDL may be formed. Openings OP_R, OP_G, and OP_B may be defined through the pixel definition layer PDL, and the pixel electrodes AE-R, AE-G, and AE-B may be exposed without being covered by the pixel definition layer PDL.

In case that the deposition process is performed in the deposition chamber DPA, the first functional layer HFL may be formed on the work substrate before deposition WS1, and thus the work substrate after deposition WS2 may be formed. The first functional layer HFL formed on the work substrate after deposition WS2 may overlap all the openings OP_R, OP_G, and OP_B. For example, the mask MSK may be provided with an opening defined therethrough to correspond to an entire area of the substrate 110, and the deposition source DS may provide an organic material corresponding to the first functional layer HFL.

A subsequent deposition process may be performed in the same chamber using another mask. According to an embodiment, the subsequent deposition process may be performed in another deposition chamber using another mask. The display panels DP and DP-Q may be formed through various processes and are not particularly limited.

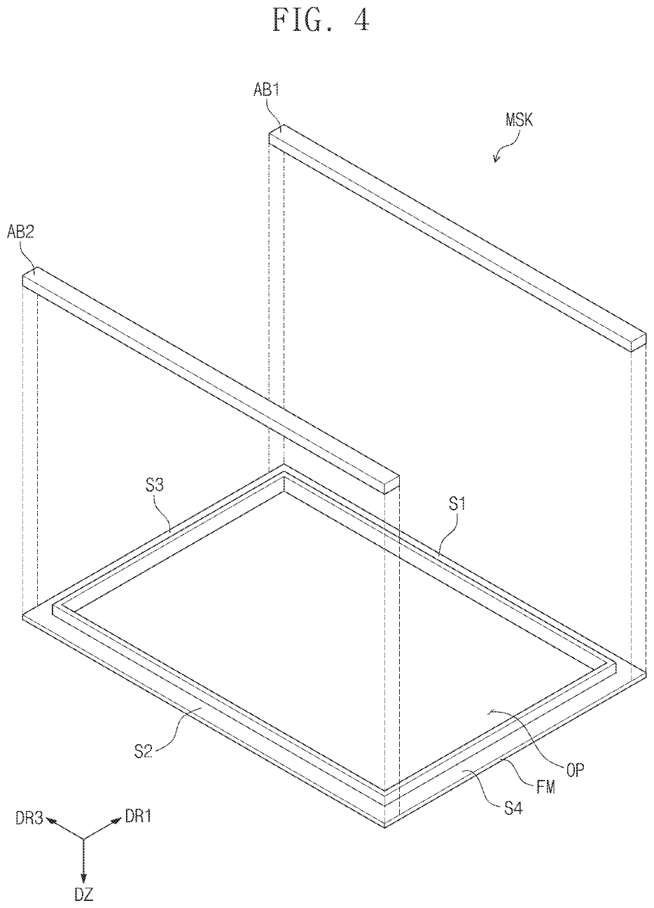

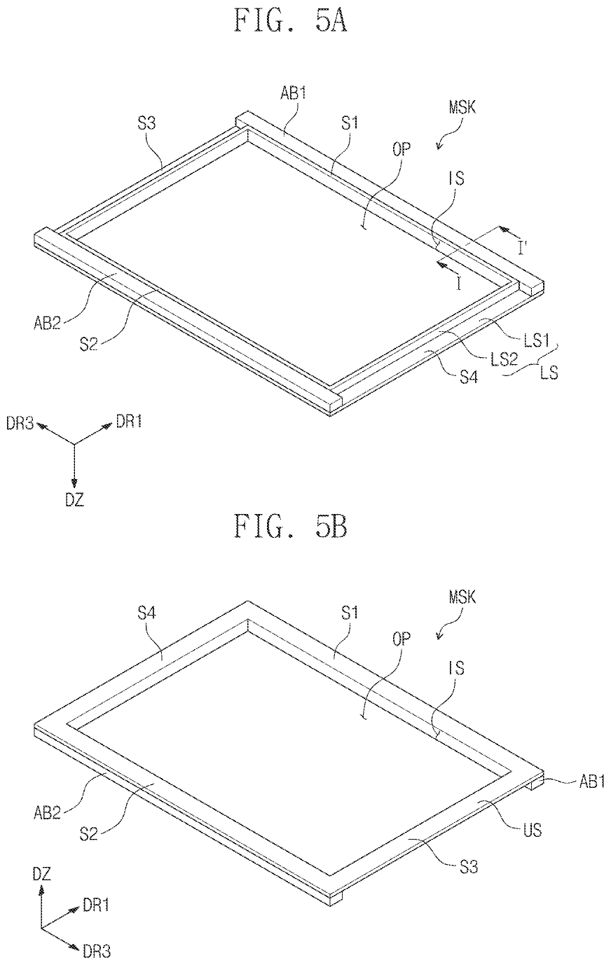

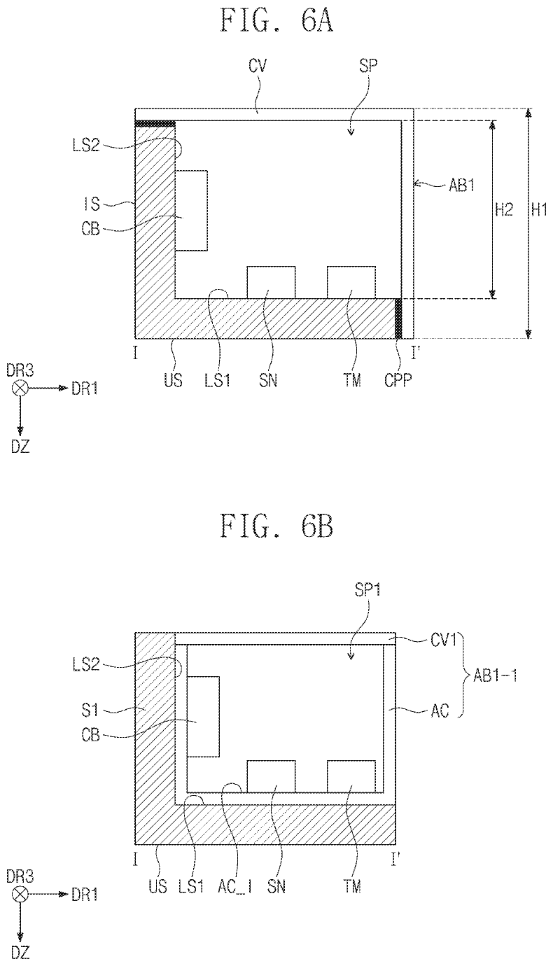

FIG. 4 is an exploded schematic perspective view of the mask MSK according to an embodiment of the disclosure. FIGS. 5A and 5B are assembled schematic perspective views of the mask MSK according to an embodiment of the disclosure. FIGS. 6A and 6B are schematic cross-sectional views of a portion of the mask MSK according to embodiments of the disclosure. Hereinafter, the mask MSK of the disclosure will be described in detail with reference to FIGS. 4, 5A, 5B, 6A, and 6B.

The mask MSK may include a frame FM, and accommodation structure. The accommodation structure may take many forms and, in an embodiment, may include a first accommodation part AB1 and a second accommodation part AB2. First accommodation part AB1 and second accommodation part AB2 may be embodied, for example, as a first space box, and a second space box. In an embodiment, the accommodation structure may include surfaces meeting at about 90 degrees (e.g., square edges). In other embodiments, the accommodation structure may include rounded edges. In yet other embodiments, the accommodation structure may not have edges between surfaces. The frame FM may include a metal material. As an example, the frame FM may include nickel (Ni), nickel-cobalt alloy, or nickel-iron alloy.

The frame FM may have a quadrangular shape in a plan view. The frame FM may be provided with an opening OP defined therein. The frame FM may have a quadrangular ring shape in a plan view. The frame FM may include four portions S1, S2, S3, and S4.

The frame FM may include a first portion S1 and a second portion S2, which extend in the third direction DR3. The first portion S1 and the second portion S2 may face each other in the first direction DR1. The frame FM may include a third portion S3 and a fourth portion S4, which extend in the first direction DR1. The third portion S3 may connect an end of the first portion S1 and an end of the second portion S2, and the fourth portion S4 may connect another end of the first portion S1 and another end of the second portion S2. The first to fourth portions S1 to S4 may be coupled to each other by welding or may be provided integrally with each other.

Each of the first to fourth portions S1 to S4 may be provided with a stepped area defined therein. The stepped area may be defined in a lower surface LS. The stepped areas may be defined outside the opening OP. The first accommodation part AB1 may be disposed in the stepped area of the first portion S1, and the second accommodation part AB2 may be disposed in the stepped area of the second portion S2.

In detail, referring to FIGS. 5A and 5B, the frame FM may include an upper surface US, the lower surface LS, and an inner surface IS. The upper surface US may be exposed to the deposition material in the deposition chamber DPA (refer to FIG. 2) and may face a ceiling of the first path PS1 (refer to FIG. 1). The lower surface LS may face the upper surface US. The inner surface IS of the first to fourth portions S1 to S4 may define the opening OP.

The lower surface LS may include a first outer surface LS1 and a second outer surface LS2. The first outer surface LS1 and the second outer surface LS2 may be connected to each other and the first outer surface LS1 may face the upper surface US. The first outer surface LS1 and the second outer surface LS2 may define the stepped areas of the first to fourth portions S1 to S4.

The first accommodation part AB1 and the second accommodation part AB2 may be disposed to face each other in the first direction DR1. Each of the first accommodation part AB1 and the second accommodation part AB2 may accommodate multiple sensors or a driving circuit therein.

FIG. 6A is a cross-sectional view taken along line I-I′ shown in FIG. 5A. Referring to FIG. 6A, the accommodation structure (e.g., first accommodation part AB1) may provide an accommodation space SP (e.g., an inner space). The accommodation space SP may be embodied in multiple spaces (e.g., a first part accommodation space and a second part accommodation space). The accommodation space SP may be in the atmosphere state. The accommodation space SP may be defined by a cover CV and the stepped area of the first portion S1. The cover CV may have a size and a shape, which may be enough to cover the stepped area, i.e., the first outer surface LS1 and the second outer surface LS2 of the first portion S1.

The cover CV may be provided to entirely cover the first outer surface LS1 and the second outer surface LS2 of the first portion S1 and may cover an area corresponding to a thickness H1 of the mask MSK. Since the second outer surface LS2 may be connected to the first outer surface LS1 and defines the stepped area, the accommodation space SP may be defined in an area corresponding to a height H2 of the second outer surface LS2. As an example, in case that the thickness H1 of the mask MSK is about 50 mm, the height H2 of the accommodation space SP may be about 35 mm. According to an embodiment, the accommodation space SP may be provided within a range of the thickness H1 of the mask MSK, and thus, the accommodation parts AB1 and AB2 may be provided without changing a shape or a design of a conventional mask MSK.

The cover CV and the first portion S1 may be coupled to each other by a coupling member CPP, and thus, the accommodation space SP shielded from the outside may be provided. The mask MSK may shield the accommodation space SP, and thus, the atmosphere state of the accommodation space SP, which may be independently maintained from the outside, may be stably provided even though the outside of the accommodation space SP may be changed to the vacuum state or a state different from the atmosphere state.

A sensor SN, a driving circuit CB, and a communication module (e.g., a transmitter, receiver, and/or transceiver) TM may be disposed in the accommodation space SP. In an embodiment, the sensor SN and the communication module TM may be disposed on the first outer surface LS1, and the driving circuit CB may be disposed on the second outer surface LS2, however, this is merely an example. According to an embodiment, the sensor SN, the driving circuit CB, and the communication module TM may be disposed on one outer surface and are not particularly limited. Although not shown in figures, a battery may be further disposed in the accommodation space SP to supply a power to the sensor SN, the driving circuit CB, and the communication module TM.

The driving circuit CB may be electrically connected to the sensor SN and the communication module TM via a line (not shown). In an embodiment, the sensor SN or the communication module TM is separated from the driving circuit CB, however, embodiments are not limited thereto or thereby. The driving circuit CB may be provided in the form of a circuit board on which the sensor SN or the communication module TM may be mounted. The driving circuit CB may include a controller, a power supply, a charging port, various vacuum feedthroughs, or the like. The driving circuit CB may drive the sensor SN and the communication module TM and may receive, store, and process electrical signals generated from the sensor SN and the communication module TM.

The sensor SN may collect status information of the mask MSK. In detail, the sensor SN may be at least one of a gyro sensor, a vibration sensor, a displacement sensor, and an optical sensor. The sensor SN may detect a position, a movement, a movement speed of the mask MSK, and whether there is a collision of mask MSK and may generate the status information of the mask MSK and internal status information of the substrate transfer apparatus SYS.

The communication module TM may transmit a signal via a wireless network. The wireless network may be a network such as a ZigBee network, a Bluetooth network, or a Z-wave network. The communication module TM may further include a wired communication module between the sensor SN and the driving circuit CB. The communication module TM may be included in the driving circuit CB, and embodiments are not particularly limited.

The status information of the mask MSK may be transmitted to the outside of the substrate transfer apparatus SYS (refer to FIG. 1) via the communication module TM. Accordingly, the state of the mask MSK may be monitored in real time within a movement path of the mask MSK. A control signal from the outside of the substrate transfer apparatus SYS may be applied to the driving circuit CB via the communication module TM, or a robot arm installed in the substrate transfer apparatus SYS may be controlled by the control signal. Accordingly, the sensor SN or the internal environment, e.g., the state of the path, of the substrate transfer apparatus SYS may be readily controlled from the outside of the substrate transfer apparatus SYS, a maintenance and repair work of the substrate transfer apparatus SYS may be simplified.

Referring to FIG. 6B, a first accommodation part AB1-1 may provide an accommodation space SP1 independent from a first portion S1. The first accommodation part AB1-1 may include an accommodation portion AC and a cover CV1. The accommodation portion AC may include an inner surface AC_I that defines an accommodation space and may be disposed in the first portion S1. A sensor SN, a communication module TM, and a driving circuit CB may be disposed on the inner surface AC_I of the accommodation portion AC. As described above, the first accommodation part AB1-1 may be assembled independently from a frame FM and may be installed at the first portion S1, however, embodiments are not limited thereto or thereby.

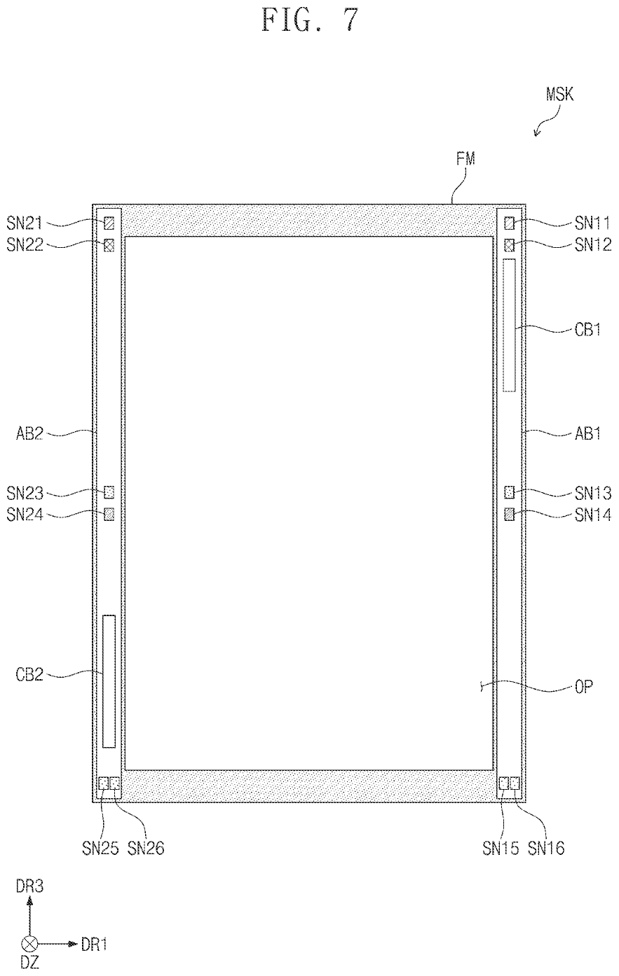

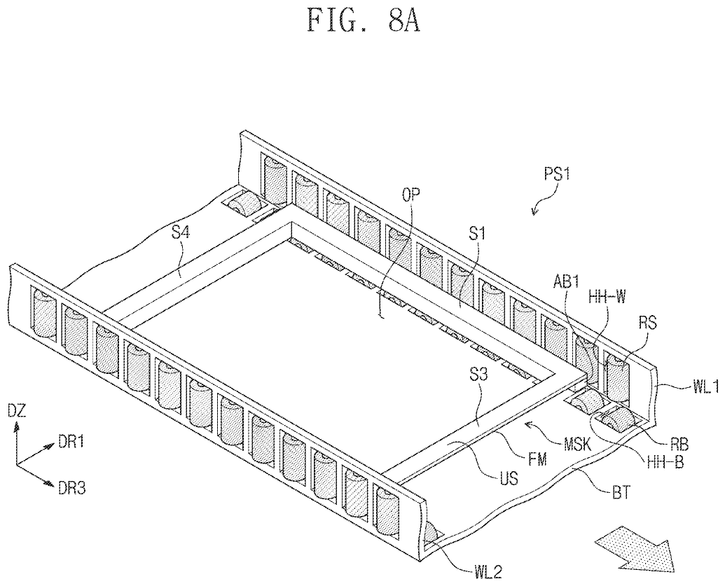

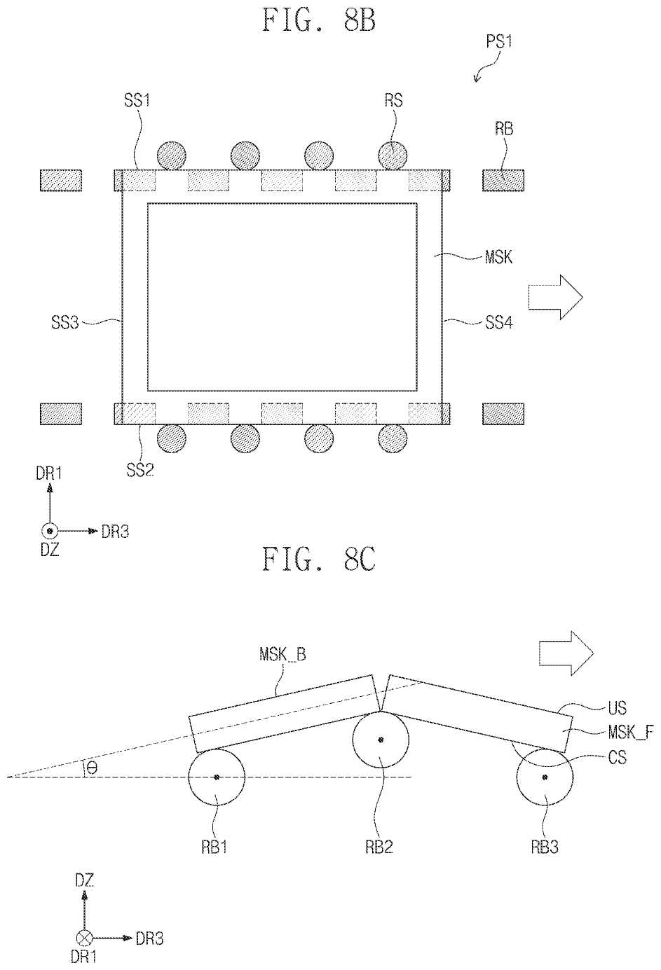

FIG. 7 is a schematic plan view of the mask MSK according to an embodiment of the disclosure. FIGS. 8A to 8C are schematic views of a portion of the path PS1 according to an embodiment of the disclosure. FIG. 8A is a perspective view of the first path PS1, and FIG. 8B is a plan view of the first path PS1. FIG. 8C is a side view of the first path PS1. Each of the other paths PS2, PS3, PS4, and PS5 shown in FIG. 1 may have a structure corresponding to the first path PS1. Hereinafter, the first path PS1 and the mask MSK passing through the first path PS1 will be described with reference to FIGS. 7 and 8A to 8C.

Referring to FIG. 7, each of the first accommodation part AB1 and the second accommodation part AB2 may include multiple sensors and driving circuits. In an embodiment, for convenience of explanation, the communication module is not illustrated.

In detail, the first accommodation part AB1 may include six sensors SN11, SN12, SN13, SN14, SN15, and SN16 and a driving circuit CB1. The sensors SN11, SN12, SN13, SN14, SN15, and SN16 may include a displacement sensor SN11, a side displacement sensor SN12, a gyro sensor SN13, a vibration sensor SN14, and optical sensors SN15 and SN16. The optical sensors SN15 and SN16 may be, for example, cameras. Among the sensors SN11, SN12, SN13, SN14, SN15, and SN16, the displacement sensor SN11 or the side displacement sensor SN12 may be arranged to be relatively closer to the outside of the mask MSK compared to the gyro sensor SN13 or the vibration sensor SN14.

The displacement sensor SN11 or the side displacement sensor SN12 may be non-contact displacement sensors. The displacement sensor SN11 or the side displacement sensor SN12 may measure a movement amount of an object, e.g., the mask MSK in an embodiment. Accordingly, information about the movement amount of the mask MSK may be monitored. As an example, the displacement sensor SN11 or the side displacement sensor SN12 may be used to monitor information related to the mask MSK, e.g., a movement speed, a movement distance, a height, a thickness, a width, etc.

The displacement sensor SN11 or the side displacement sensor SN12 may measure a difference in level between bottom rollers RB and a difference in level between side rollers RS and may measure an alignment state or position information of the rollers RB and RS of the first path PS1 (refer to FIG. 1). For example, information about the status of the substrate transfer apparatus may be monitored via the displacement sensor SN11 or the side displacement sensor SN12.

In an embodiment, the displacement sensor SN11 or the side displacement sensor SN12 may be disposed in the first accommodation part AB1 (e.g., in an accommodation space). Accordingly, the displacement sensor SN11 or the side displacement sensor SN12 may be operated stably in an atmospheric pressure environment without being affected by changes in air pressure inside the substrate transfer apparatus. However, this is merely an example. Since the displacement sensor SN11 or the side displacement sensor SN12 is relatively less affected by the changes in air pressure, the displacement sensor SN11 or the side displacement sensor SN12 may be disposed outside the first accommodation part AB1, and embodiments are not particularly limited.

The gyro sensor SN13 may measure a value of a rotational speed (angular velocity) of an object, e.g., the mask MSK, and thus, the movement path or changes in orientation of the mask MSK may be monitored in real time. The gyro sensor SN13 may measure a triaxial angular velocity. As the gyro sensor SN13 may be disposed in the first accommodation part AB1, the gyro sensor SN13 may be operated stably without being affected by the changes in air pressure in the substrate transfer apparatus.

The vibration sensor SN14 may be an acceleration sensor, in detail, a triaxial acceleration sensor. The vibration sensor SN14 may measure the acceleration speed to measure a vibration of the mask MSK. The vibration of the mask MSK may include vibrations generated by the mask MSK itself or vibrations generated from the substrate transfer apparatus, e.g., the first path, and transmitted to the mask MSK. The vibration sensor SN14 may be disposed in the first accommodation part AB1, and thus, the vibration sensor SN14 may be operated stably in atmospheric pressure without being affected by the changes in air pressure in the substrate transfer apparatus.

The optical sensors SN15 and SN16 may observe the inside of the substrate transfer apparatus and may monitor the status of the inside of the substrate transfer apparatus in real time based on image information about the status of the inside of the substrate transfer apparatus in real time. As the optical sensors SN15 and SN16 may be disposed in the first accommodation part AB1, the optical sensors SN15 and SN16 may be operated stably in atmospheric pressure without being affected by the changes in air pressure in the substrate transfer apparatus.

For convenience of explanation, the second accommodation part AB2 shown in FIG. 7 may have a structure corresponding to that of the first accommodation part AB1. Accordingly, six sensors SN21, SN22, SN23, SN24, SN25, and SN26 are shown to correspond to those of the first accommodation part AB1. A second driving circuit CB2 is shown to be arranged diagonally with the first driving circuit CB1. However, this is merely an example, and according to an embodiment, the second accommodation part AB2 may be designed independently from the first accommodation part AB1 and are not particularly limited.

According to an embodiment, as the accommodation parts AB1 and AB2 may be disposed overlapping the frame FM, an interference to the opening OP area may not occur. Accordingly, in case that the deposition process is performed using the mask MSK, the deposition area may be readily secured, and the state of the mask MSK may be monitored without changes in design of the conventional substrate transfer apparatus. Thus, the deposition process may be simplified, and the process cost may be reduced.

Referring to FIG. 8A, the first path PS1 may include the transfer guide through which the mask MSK moves. In detail, the transfer guide may include a bottom portion BT, a first sidewall portion WL1, a second sidewall portion WL2, and the rollers RB and RS. The bottom portion BT may extend in the third direction DR3 and may have a width in the first direction DR1 enough to move the mask MSK. In an embodiment, since the mask MSK moves in a long side direction thereof, the width in the first direction DR1 of the bottom portion BT may be equal to or greater than a length of a short side of the mask MSK.

The first sidewall portion WL1 and the second sidewall portion WL2 may be connected to the bottom portion BT and may face each other in the first direction DR1. The first sidewall portion WL1 and the second sidewall portion WL2 may protrude from the bottom portion BT to a direction DZ (hereinafter, referred to as an upward direction) toward a ceiling of the first path PS1.

The side rollers RS may be inserted into each of the first sidewall portion WL1 and the second sidewall portion WL2. Each of the side rollers RS may be rotated with respect to a rotational axis extending in a direction substantially parallel to the upward direction DZ. The side rollers RS may be in contact with the first portion S1 and a second portion (not shown) of the mask MSK and may move the mask MSK in the third direction DR3.

In detail, referring to FIG. 8B, a side surface SS1 of the first portion S1 and a side surface SS2 of the second portion of the mask MSK may be in contact with the side rollers RS, and the mask MSK may move in the first path PS1. The side rollers RS may control a moving direction of the mask MSK. For example, the movement path of the mask MSK may vary depending on a direction in which the side rollers RS may be arranged, and a shape of the first path PS1 may be determined.

In the first path PS1, a side surface SS3 of the third portion S3 and a side surface SS4 of the fourth portion S4 of the mask MSK may not be in contact with the side rollers RS. Accordingly, the mask MSK may move along the long side direction, i.e., the third direction DR3. However, this is merely an example. The mask MSK may move in a short side direction, and the side rollers RS may be in contact with the side surface SS3 of the third portion S3 and the side surface SS4 of the fourth portion S4 of the mask MSK.

The side surfaces SS1 and SS2 that make contact with the side rollers RS may be the accommodation parts AB1 and AB2. In detail, the side surfaces SS1 and SS2 may be the cover CV (refer to FIG. 6A) of the accommodation parts AB1 and AB2 or may be outer surfaces of the accommodation portion AC (refer to FIG. 6B). Accordingly, the contact status or collision between the side rollers RS and the mask MSK may be readily sensed by the sensors provided inside the accommodation structure (e.g., accommodation parts AB1 and AB2).

In an embodiment, the mask MSK may be in contact with the side rollers RS while moving, however, this is merely an example. According to an embodiment, the mask MSK may be spaced apart from the side rollers RS by a distance while moving and may be in contact with the side rollers RS only in case that there is a change in the movement direction.

Referring to FIGS. 8A to 8C, the bottom rollers RB may be inserted into the bottom portion BT. Each of the bottom rollers RB may be rotated with respect to a rotational axis extending in the direction substantially parallel to the first direction DR1. The bottom rollers RB may be in contact with the lower surface LS of the mask MSK, e.g., the covers CV and CV1 of the accommodation parts AB1 and AB2 disposed on the lower surface LS and may move the mask MSK in the third direction DR3. The bottom rollers RB may face the lower surface LS of the first portion S1 and the second portion S2 of the mask MSK. The bottom rollers RB may be in contact with the mask MSK to control the movement speed and the movement state of the mask MSK. For example, the mask MSK may be transferred by the contact between the mask MSK and the bottom rollers RB, and thus, the movement speed of the mask MSK may vary depending on the contact state between the bottom rollers RB and the mask MSK and the rotational speed of the bottom rollers RB.

As an example, in case that it is needed to move the mask MSK, the bottom rollers RB may increase the movement speed of the mask MSK by increasing the rotational speed thereof. In other embodiments, in case that the deposition process is carried out on the mask MSK inside the deposition chamber or in case that it is needed to move the mask MSK for alignment, the bottom roller RB has a relatively low rotational speed, and thus, the movement speed of the mask MSK may be lowered. The bottom rollers RB may be designed to have various rotational speeds depending on their positions and are not particularly limited.

The surfaces that may be in contact with the bottom rollers RB may be the accommodation parts AB1 and AB2. In detail, the surfaces that may be in contact with the bottom rollers RB may be the covers CV (refer to FIG. 6A) of the accommodation parts AB1 and AB2. The side rollers may be the outer surfaces of the accommodation portion AC (refer to FIG. 6B). Accordingly, the contact state between the bottom rollers RB and the mask MSK and the level difference between the bottom rollers RB may be readily measured by the sensors provided in the accommodation parts AB1 and AB2.

FIG. 8C shows three bottom rollers RB1, RB2, and RB3 that may be misaligned. The bottom roller RB2 disposed at a center position among the three bottom rollers RB1, RB2, and RB3 is protruded in the upward direction DZ. Accordingly, the bottom rollers RB1, RB2, and RB3 may be misaligned in the moving direction, i.e., the third direction DR3, of masks MSK_B and MSK_F.

Referring to the mask MSK_B in a first state passing through two bottom rollers RB1 and RB2 and the mask MSK_F in a second state passing through two bottom rollers RB2 and RB3, in case that the masks MSK_B and MSK_F pass over the bottom rollers RB1, RB2, and RB3 that may be misaligned, the masks MSK_B and MSK_F may be transferred while being inclined in the upward direction DZ by an angle θ with respect to the moving direction, i.e., the third direction DR3, of the mask MSK. For example, the movement state of the masks MSK_B and MSK_F may be changed due to the protruded roller RB2. This change may cause a decrease in movement speed of the masks MSK_B and MSK_F, a separation of the masks MSK_B and MSK_F from the movement path, or a collision between surrounding apparatuses (for example side walls) and the masks MSK_B and MSK_F.

According to the disclosure, as the mask MSK includes accommodation structure (e.g., the accommodation parts AB1 and AB2) in which the sensors may be provided, the status information of the mask MSK during the movement of the mask MSK may be collected in real time. As described above, since the sensors include the gyro sensor, the displacement sensor, the vibration sensor, and/or the optical sensor, it is possible to collect information about the change of the position of the mask MSK on the plane in the movement path, the collision, or the movement speed, etc. in real time. Accordingly, the mask MSK may be readily monitored in real time while passing through the first path PS1.

It may be possible to secure information on defects in the first path PS1, and a simple maintenance/repair work for the transfer guide may be performed in real time using the robot arm. Accordingly, even though the movement speed of the mask MSK is high, for example, even in case that the mask MSK moves at a high speed of about 600 mm/s or more, information on the state of the mask MSK or the internal state of the substrate transfer apparatus SYS may be readily secured without decreasing the movement speed.

As the accommodation parts AB1 and AB2 may be maintained in the atmospheric pressure state, the sensors may be operated in the atmospheric pressure state. Accordingly, even though an air pressure of the path or the chamber through which the mask MSK passes is changed, the sensors may be less affected. Accordingly, the status of the mask MSK in the deposition chamber may be monitored stably and continuously.

In an embodiment, the first path PS1 and the mask MSK passing through the first path PS1 are shown as a representative example. The rollers RB and RS may be applied to the other paths PS2, PS3, PS4, and PS5 and may be applied to transfer the substrate transfer member CRS or the mask assembly ASY, which moves through the other paths PS2, PS3, PS4, and PS5. This will be described in detail later. According to the disclosure, since the mask MSK, the substrate transfer member CRS, or the mask assembly ASY, which passes through the path, includes the sensors, the status of the path or the process defects may be readily monitored.

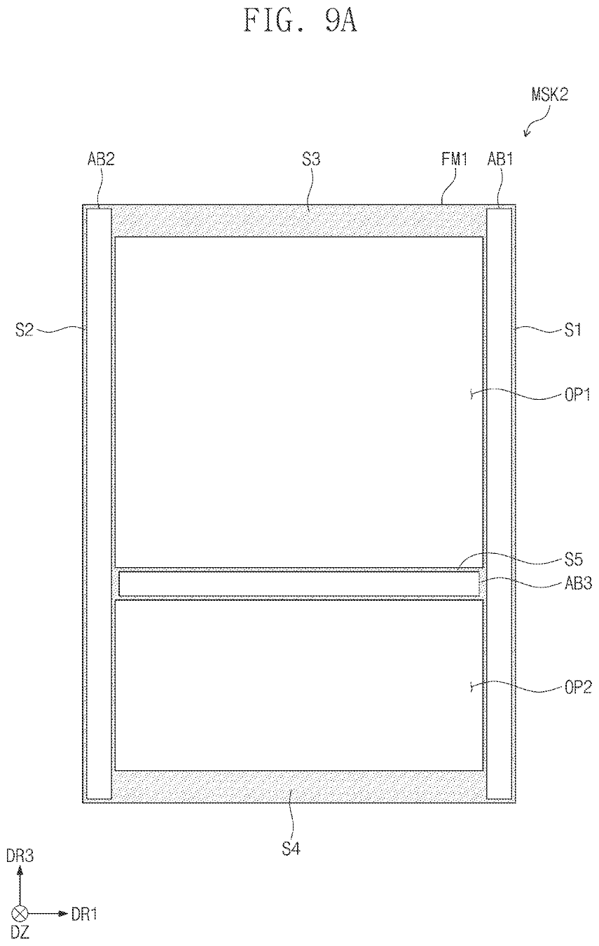

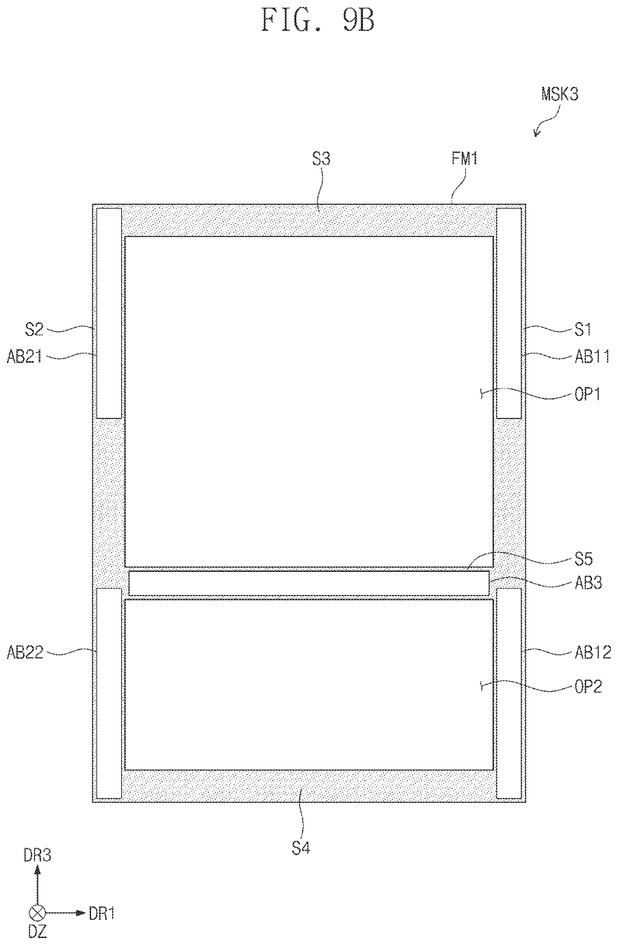

FIGS. 9A and 9B are schematic plan views of masks MSK2 and MSK4 according to embodiments of the disclosure. For convenience of explanation, some components may be omitted in the embodiments.

Referring to FIG. 9A, the mask MSK2 may include a frame FM1 through which multiple openings OP1 and OP2 may be defined and three accommodation parts AB1, AB2, and AB3. The frame FM1 may further include a fifth portion S5 compared to the frame FM shown in FIG. 7. The fifth portion S5 may extend in the first direction DR1 and may be connected to a first portion S1 and a second portion S2.

The fifth portion S5 may cross the opening OP shown in FIG. 7. Accordingly, different from the mask MSK shown in FIG. 7, the mask MSK2 may be provided with two openings OP1 and OP2. For example, the mask MSK2 may include a deposition area different from that of the mask MSK shown in FIG. 7.

The mask MSK2 may further include a third accommodation part AB3. The third accommodation part AB3 may be disposed on the fifth portion S5. In the mask MSK2, the accommodation parts AB1, AB2, and AB3 may be disposed on the frame FM1, and thus, interferences to the openings OP1 and OP2 may be reduced. Accordingly, the mask MSK2 may further include sensors, which may be capable of monitoring the state of the mask MSK2, without affecting the deposition area.

Referring to FIG. 9B, the mask MSK3 may include accommodation parts AB11, AB12, AB21, and AB22 separated from each other. The mask MSK3 may have a shape corresponding to the mask of FIG. 9A. The accommodation parts AB11, AB12, AB21, and AB22 may correspond to a structure in which each of the first and second accommodation parts AB1 and AB2 shown in FIG. 9A may be divided into two portions. Referring to FIG. 9B, the shape and the number of the accommodation parts may be changed in various ways as long as the accommodation parts may be disposed in/on the frame FM1 and are not particularly limited.

FIG. 10A is an exploded schematic perspective view of a mask MSK4 according to an embodiment of the disclosure. FIG. 10B is an assembled schematic plan view of the mask MSK4 shown in FIG. 10A. FIG. 10C is an assembled schematic perspective view of the mask MSK4 shown in FIG. 10A. Hereinafter, the mask MSK4 of the disclosure will be described in detail with reference to FIGS. 10A to 10C. In FIGS. 10A to 10C, the same reference numerals denote the same elements in FIGS. 1 to 9B, and thus, detailed descriptions of the same elements will be omitted.

Referring to FIGS. 10A to 10C, the mask MSK4 may include a frame FM, a mask sheet MS, and first, second, and third accommodation parts AB1, AB2, and AB3.

The mask sheet MS may be coupled to (i.e., welded to) the frame FM to overlap an opening OP. The mask sheet MS may include first components E1 and second components E2 that define deposition openings M-OP. In an embodiment, the first components E1 that may be vertical components may be longer than the second components E2 that may be horizontal components, however, embodiments are not limited thereto or thereby.

The first components E1 may cross (intersect) the second components E2 and may be provided integrally with the second components E2. In an embodiment, the first components E1 may extend in the third direction DR3, and the second components E2 may extend in the first direction DR1. The frame FM and the mask sheet MS may include the same material, e.g., Invar. Since the frame FM and the mask sheet MS may have the same thermal expansion coefficient, a distortion of the mask MSK4 may be reduced in the deposition process. However, a material for the frame FM and the mask sheet MS is not particularly limited. The frame FM may be omitted in an embodiment. The shape of the mask sheet MS may be maintained by increasing a thickness of outer components of the mask sheet MS.

According to an embodiment, more subdivided deposition areas may be provided with respect to the same mother substrate compared to the mask MSK (refer to FIG. 4). As the mask MSK4 further includes the mask sheet MS, the opening OP of the frame FM may be subdivided into the deposition openings M-OP smaller than the opening OP. Accordingly, the mask MSK4 may be used in a deposition process for a relatively small display panel.

The third accommodation part AB3 may be disposed overlapping the opening OP of the frame FM. The third accommodation part AB3 may be disposed overlapping some deposition openings of the deposition openings M-OP of the mask sheet MS. The deposition openings M-OP overlapping the third accommodation part AB3 may not be included in the deposition area.

The mask MSK4 may be a mask that provides the deposition openings M-OP obtained by subdividing the mask MSK2 (refer to FIG. 9A). The third accommodation part AB3 may correspond to the third accommodation part AB3 disposed between the first opening OP1 and the second opening OP2 shown in FIG. 9A. The mask MSK4 may have a structure including multiple areas obtained by subdividing an area corresponding to the first opening OP1 and multiple areas obtained by subdividing an area corresponding to the second opening OP2 by the deposition openings M-OP of the mask sheet MS.

As the third accommodation part AB3 may be disposed in the area that may not be included in the deposition area, the number of accommodation parts in the mask MSK4 may vary without affecting the deposition area. Accordingly, an area in which the accommodation part may be disposed may increase, and a degree of freedom for the arrangement of the accommodation part may be improved.

However, this is merely an example, and the third accommodation part AB3 may be omitted from the mask MSK4. All the deposition openings M-OP of the mask sheet MS in the mask MSK4 may be used as the deposition area. According to an embodiment, the third accommodation part AB3 may be disposed in another portion, e.g., the third portion S3 or the fourth portion S4, of the frame FM not to overlap the deposition openings M-OP of the mask sheet MS. According to the disclosure, monitoring of the state of the mask MSK4 and the internal state of the substrate transfer apparatus SYS may be possible while the mask MSK4 is being used for the deposition process. Accordingly, the process cost and the process time may be reduced.

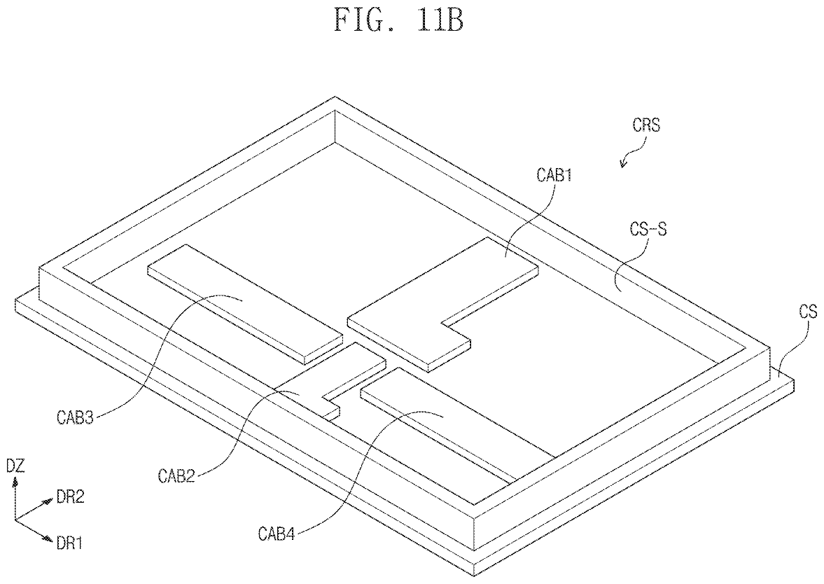

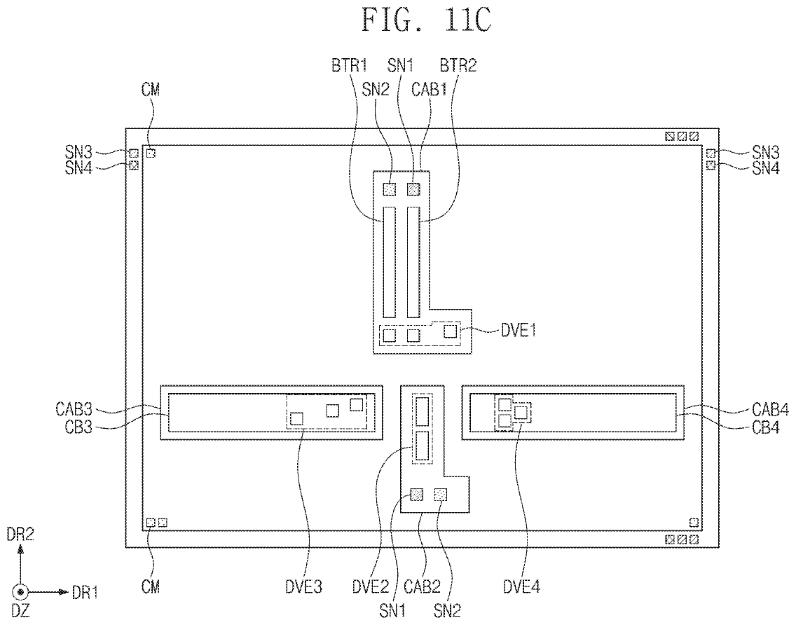

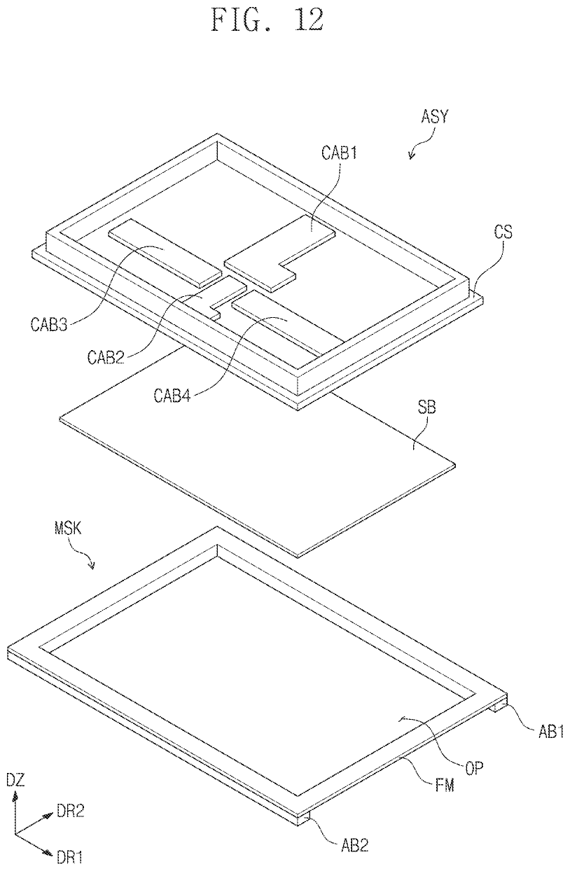

FIGS. 11A and 11B are schematic perspective views of a substrate transfer member CRS. FIG. 11C is a schematic rear view of the substrate transfer member CRS. In FIGS. 11A to 11C, for convenience of explanation, the substrate transfer member CRS is schematically illustrated, and some components may be omitted.

Referring to FIG. 11A, a substrate SB may be disposed on a carrier substrate CS. As described above, the substrate may correspond to a substrate in one of a variety of stages in the manufacturing process of the display panel. As an example, the substrate SB may be one of the work substrates WS1 and WS2 (refer to FIGS. 3A and 3B).

The substrate transfer member CRS may further include camera modules (cameras) CM1 and CM2. The camera modules CM1 and CM2 may be disposed on the carrier substrate CS and may be disposed on the same plane as the substrate SB, and thus, the camera modules CM1 and CM2 may readily take pictures of a surrounding environment or a status of the substrate SB in case that the substrate transfer member CRS moves.

FIGS. 11B and 11C show a surface of the substrate transfer member CRS that is opposite to a surface on which the substrate SB may be disposed. The carrier substrate CS may include an inner surface CS-S to define an accommodation space on the surface that may be opposite to the surface on which the substrate SB may be disposed. Multiple accommodation parts CAB1, CAB2, CAB3, and CAB4 may be disposed in the inner surface CS-S.

In detail, referring to FIG. 11C, multiple sensors SN1, SN2, SN3, and SN4, a camera module CM, multiple driving circuits CB1 and CB2, driving devices DVE1, DVE2, and DVE3, and the accommodation parts CAB1, CAB2, CAB3, and CAB4 may be disposed in the surface of the carrier substrate CS on which the inner surface CS-S is disposed.

Each of the sensors SN1, SN2, SN3, and SN4 may include at least one of the gyro sensor, the vibration sensor, and a touch sensor. The sensors SN1, SN2, SN3, and SN4 may sense the position, the movement, the movement speed, and the collision of the substrate transfer member CRS and may generate the status information of the substrate transfer member CRS.

Among the sensors SN1, SN2, SN3, and SN4, a first sensor SN1 and a second sensor SN2 may be disposed in the accommodation parts CAB1 and CAB2, and a third sensor SN3 and a fourth sensor SN4 may be disposed outside the accommodation parts CAB1, CAB2, CAB3, and CAB4. The first sensor SN1 and the second sensor SN2 may be operated under the atmospheric pressure state, and the third sensor SN3 and the fourth sensor SN4 may be operated under both the atmospheric pressure state and the vacuum state. Descriptions of sensors may be the same as those described above.

As an example, the first sensor SN1 may be the vibration sensor. The first sensor SN1 may be the acceleration sensor, in detail, the three-axial acceleration sensor. The first sensor SN1 may measure the acceleration speed to measure the vibration of the substrate transfer member CRS. The vibration of the substrate transfer member CRS may include vibrations generated by the mask MSK itself or vibrations generated in the second path, and transmitted to the substrate transfer member CRS. The first sensor SN1 may be disposed in the accommodation parts CAB1 and CAB2, and thus, the first sensor SN1 may be operated stably under the atmospheric pressure state without being affected by the changes in air pressure in the second path.

The second sensor SN2 may be the gyro sensor. The second sensor SN2 may measure a value of a rotational speed (angular velocity) of an object, e.g., the substrate transfer member CRS, and thus, a movement path or changes in orientation of the substrate transfer member CRS may be monitored in real time. The gyro sensor may measure a triaxial angular velocity. As the second sensor SN2 may be disposed in the accommodation parts CAB1 and CAB2, the second sensor SN2 may be operated stably without being affected by the changes in air pressure in the substrate transfer apparatus.

The third sensor SN3 may be the displacement sensor, and the fourth sensor SN4 may be the side surface displacement sensor. Each of the third sensor SN3 and the fourth sensor SN4 may be the non-contact displacement sensors. The third sensor SN3 or the fourth sensor SN4 may measure a movement amount of an object, e.g., the substrate transfer member CRS, in an embodiment. Accordingly, information about the movement amount of the substrate transfer member CRS may be monitored. As an example, the third sensor SN3 and the fourth sensor SN4 may be used to monitor information related to the substrate transfer member CRS, e.g., a movement speed, a movement distance, a height, a thickness, a width, etc.

According to the disclosure, as the accommodation structure (e.g., accommodation parts CAB1, CAB2, CAB3, and CAB4) may be provided, the sensors SN1 and SN2 operated under the atmospheric pressure environment may also be used to monitor the substrate transfer member CRS.

The third sensor SN3 or the fourth sensor SN4 may measure an alignment state or position information of the rollers of the second path PS2 (refer to FIG. 4). For example, information related to the status of the rollers may be monitored using the third sensor SN3 or the fourth sensor SN4. In an embodiment, the third sensor SN3 or the fourth sensor SN4 may be disposed outside of the accommodation parts CAB1, CAB2, CAB3, and CAB4, and the third sensor SN3 or the fourth sensor SN4 may be disposed in an edge of the carrier substrate CS. Accordingly, the third sensor SN3 or the fourth sensor SN4 may be disposed closer to an outer boundary of the carrier substrate CS than the accommodation parts CAB1, CAB2, CAB3, and CAB4 are, and thus, the third sensor SN3 or the fourth sensor SN4 may directly measure a contact between the substrate transfer member CRS and the apparatus or the position information of the apparatus. Accordingly, a sensitivity and an accuracy of the third sensor SN3 or the fourth sensor SN4 may be improved.

In FIG. 11C, for convenience of explanation, the same type of sensors have the same hatching pattern, and thus, reference numerals of the same elements may be omitted to avoid redundancy. The sensors shown in FIG. 11C are merely an example, and the sensors are not particularly limited. For example, the substrate transfer member CRS may further include more sensors, and arrangement positions of the sensors may be designed in various ways.

The driving devices DVE1, DVE2, DVE3, and DVE4 may be electrically connected to the sensors SN1, SN2, SN3, and SN4. Each of the driving devices DVE1, DVE2, DVE3, and DVE4 may include various elements forming the driving circuit or the communication module. The driving devices DVE1, DVE2, DVE3, and DVE4 may be disposed in the accommodation parts CAB1, CAB2, CAB3, and CAB4, respectively.

As an example, first driving devices DVE1 may be disposed in a first accommodation part CAB1 and may be electrically connected to the sensors SN1 and SN2 or batteries BTR1 and BTR2. Second driving devices DVE2 may be disposed in a second accommodation part CAB2 and may be electrically connected to the sensors SN1 and SN2.

Third driving devices DVE3 may be disposed in a third accommodation part CAB3 and may be mounted on a first circuit substrate CB1. Fourth driving devices DVE4 may be disposed in a fourth accommodation part CAB4 and may be mounted on a second circuit substrate CB2. Each of the first circuit substrate CB1 and the second circuit substrate CB2 may be electrically connected to objects provided outside the accommodation parts CAB3 and CAB4 via wires (not shown).

According to the disclosure, the carrier substrate CS may include the sensors SN1, SN2, SN3, and SN4 and the camera modules CM, CM1, and CM2, and thus, the status information of the substrate transfer member CRS may be collected in real time in the process of moving the substrate transfer member CRS. Accordingly, the movement of the substrate transfer member CRS and the environment of the path through which the substrate transfer member CRS moves may be monitored in real time.

According to the disclosure, as the accommodation structure (e.g., accommodation parts CAB1, CAB2, CAB3, and CAB4) may be provided, various components operated under the atmospheric environment, such as the sensors SN1 and SN2, the driving devices DVE1 and DVE2, and the batteries BTR1 and BTR2, may be used to monitor the substrate transfer member CRS. Accordingly, various electronic components may be operated stably without being affected by changes in air pressure inside the substrate transfer apparatus, and thus, the status information of the substrate transfer member CRS may be stably collected in various environments of the path.

FIG. 12 is an exploded schematic perspective view of a mask assembly ASY according to an embodiment of the disclosure. Referring to FIG. 12, the mask assembly ASY may include the mask MSK, the substrate SB, and the carrier substrate CS. The mask MSK, the substrate SB, and the carrier substrate CS may be sequentially stacked along the upward direction DZ and may be coupled to each other.

The mask assembly ASY may include two accommodation parts AB1 and AB2 disposed in the mask MSK and four accommodation parts CAB1, CAB2, CAB3, and CAB4 disposed in the carrier substrate CS. The sensors may be disposed in each of the accommodation parts AB1, AB2, CAB1, CAB2, CAB3, and CAB4 and outside of the accommodation parts AB1, AB2, CAB1, CAB2, CAB3, and CAB4. FIG. 12 shows a stack structure of the mask assembly ASY in case that the mask assembly ASY moves through the path, e.g., the fourth path PS4 (refer to FIG. 1). For example, in case that the mask assembly ASY passes through the path, the mask MSK may be in contact with the rollers RB and RS (refer to FIG. 8A), and the status information of the mask assembly ASY and the status information of the path may be measured by the sensors included in the mask MSK. However, this is merely an example, and information measured by the sensors included in the carrier substrate CS may be used to monitor the status of the path or the status of the mask assembly ASY in addition to the sensors included in the mask MSK. However, embodiments are not limited thereto or thereby.

According to the disclosure, the status of the mask assembly ASY may be monitored while the mask assembly ASY may be moving through the path based on the status information collected by the sensors of the mask MSK or the sensors of the carrier substrate CS. As the information of the mask assembly ASY, such as the movement speed, whether the collision occurs during the movement of the mask assembly ASY, and an equilibrium state during the movement of the mask assembly ASY, may be monitored by the sensors of the mask MSK or the sensors of the carrier substrate CS, the alignment state of the fourth path PS4 and the movement environment of the mask assembly ASY may be monitored. This is merely an example. The status information of the mask assembly ASY may be monitored by the sensors of the mask MSK and/or the sensors of the carrier substrate CS, and the disclosure is not particularly limited.

Although embodiments of the disclosure have been described, it is understood that the disclosure is not limited to these embodiments. Rather, various changes and modifications can be made by one of ordinary skill in the art within the spirit and scope of the disclosure.

What is claimed is:

1. A mask comprising:
a frame including an opening;
accommodation structure disposed on the frame and defining an accommodation space shielded from an outside; and
a sensor disposed in the accommodation space.

2. The mask of claim 1, wherein the sensor comprises at least one of a displacement sensor, a gyro sensor, and a vibration sensor.

3. The mask of claim 2, further comprising:
a camera attached to the frame.

4. The mask of claim 2, further comprising:
a communication transceiver electrically connected to the sensor.

5. The mask of claim 2, further comprising:
a driving circuit disposed in the accommodation space and electrically connected to the sensor.

6. The mask of claim 2, further comprising:
a driving circuit electrically connected to the sensor, wherein
the accommodation structure includes a first accommodation part defining a first part accommodation space and a second accommodation part defining a second part accommodation space,
the sensor is disposed in the first part accommodation space, and
the driving circuit is disposed in the second part accommodation space.

7. The mask of claim 6, wherein the second accommodation part at least partially overlaps the opening in a plan view.

8. The mask of claim 7, wherein
the frame further comprises a portion overlapping the second accommodation part and crossing the opening, and
the opening is divided into two openings by the portion.

9. The mask of claim 1, further comprising:
a mask sheet disposed on the frame and including mask openings defined through the mask to overlap the opening in a plan view.

10. The mask of claim 9, wherein the accommodation structure is disposed on the mask sheet and overlaps at least a portion of the mask openings of the mask sheet.

11. The mask of claim 1, wherein
the accommodation structure comprises a cover physically connected to the frame,
the frame and the cover together define the accommodation space, and
the accommodation space has atmospheric pressure.

12. The mask of claim 1, wherein
the accommodation structure comprises:
an accommodation portion disposed on the frame; and
a cover covering the accommodation portion,
the accommodation portion and the frame together define the accommodation space, and
the accommodation space has atmospheric pressure.

13. A mask assembly comprising:
a mask comprising:
a frame including:
an opening; and
a first sensor; and
accommodation structure defining an accommodation space;
a carrier substrate disposed on the mask and comprising:
a side facing the mask; and
another side opposite to the side facing the mask; and
a substrate disposed between the mask and the carrier substrate and provided to the side facing the mask,
wherein the first sensor is accommodated in the accommodation space.

14. The mask assembly of claim 13, wherein the first sensor comprises at least one of a gyro sensor, a vibration sensor, and a displacement sensor.

15. The mask assembly of claim 13, wherein the carrier substrate further comprises:
a camera; and
a second sensor.

16. The mask assembly of claim 15, wherein
the carrier substrate further includes another accommodation structure defining another accommodation space,
the second sensor is accommodated in the another accommodation space, and
at least one of the accommodation space and the another accommodation space has atmospheric pressure.

17. The mask assembly of claim 16, wherein the another accommodation space includes a first accommodation part and a second accommodation part, that are of the another side of the carrier substrate.

18. A substrate transfer apparatus comprising:
a path providing a vacuum state;
a transfer guide disposed in the path and comprising:
bottom rollers; and
side rollers, and
a mask moving along the transfer guide, the mask comprising:
a frame including an opening;
accommodation structure disposed on the frame and including accommodation space; and
a sensor disposed in the accommodation space.

19. The substrate transfer apparatus of claim 18, wherein
the sensor comprises at least one of a gyro sensor, a vibration sensor, and a displacement sensor, and
at least one of the bottom rollers and the side rollers are in physical contact with the accommodation structure.

20. The substrate transfer apparatus of claim 18, further comprising:
an inner communication transceiver disposed on the mask; and
an external communication transceiver disposed outside the path to transmit and receive a signal to and from the inner communication transceiver.
